(19) United States
(12) Patent Application Publication
(10) Pub. No.: US 2024/0256750 A1
(43) Pub. Date: Aug. 1, 2024

(54) MULTI-BIT FLIP-FLOP REGION WITH SERPENTINE DATA FLOW PATH, SEMICONDUCTOR DEVICE INCLUDING SAME, METHOD OF OPERATING SAME AND METHOD OF MANUFACTURING SAME

(71) Applicant: TAIWAN SEMICONDUCTOR MANUFACTURING COMPANY, LTD., Hsinchu (TW)

(72) Inventors: Chih-Cheng CHUANG, Hsinchu (TW); Hui-Zhong ZHUANG, Hsinchu (TW); Chih-Liang CHEN, Hsinchu (TW); Wei-Hsiang MA, Hsinchu (TW)

(21) Appl. No.: 18/160,697

(22) Filed: Jan. 27, 2023

(51) Int. Cl. G06F 30/392; G06F 30/394; H03K 3/356

(52) U.S. Cl. CPC G06F 30/392; G06F 30/394; H03K 3/356156

(57) ABSTRACT

A semiconductor device includes: single-bit flip-flop regions (SBFF regions) which comprise a multi-bit flip-flop (MBFF) region; the MBFF region having a two-dimensional floor plan represented by a grid including rows and a first column extending in corresponding first and perpendicular second directions, each SBFF region representing an intersection of a corresponding row and column; the SBFF regions being coupled in a daisy chain for which an output of a preceding one of the SBFF regions in the daisy chain is coupled to an input of a succeeding one of the SBFF regions in the daisy chain; and orientations of the SBFF regions relative to the first direction (α-orientations) being arranged in an alternating pattern relative to the second direction so that a two-dimensional representation of a flow path of a data signal along the first column has a serpentine shape.

### BACKGROUND

In the integrated circuit (IC) industry, flip-flops (latches) are used as data storage elements. In some circumstances, a flip-flop stores a single-bit (binary digit) of data and is referred to as a single-bit flip-flop (SBFF). In some circumstances, SBFFs are grouped to form a multi-bit flip-flop (MBFF). In some circumstances, the SBFF regions of the MBFF are coupled in a daisy chain between an input and an output of the MBFF. for which an output of a preceding one of the SBFF regions in the daisy chain is coupled to an input of a succeeding one of the SBFF regions in the daisy chain. In some circumstances, a flip-flop (latch) is used for storage of a state and represents a basic storage element of sequential logic in electronics, e.g., shift registers.

One type of flip-flop is a delay (D) flip-flop (FF). A D FF is a digital electronic circuit that delays the change of state of its output signal (Q) until the next rising edge of a clock timing input signal occurs. The D FF is a modified Set-Reset flip-flop with the addition of an inverter to prevent the S and R inputs from being at the same logic level.

A type of D FF is a scan D FF (SDFQ) which is used, e.g., to implement design for testing (DFT). A SDFQ is a D flip-flop that includes a multiplexer to controllably select between an input D during normal operation and a Scan input during scan/testing operation. Scan flip-flops, e.g., SDFQs, are used extensively for device testing.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIGS. 1A-1I are corresponding block diagrams of a semiconductor device, in accordance with some embodiments.

FIGS. 2A-2E are corresponding layout diagrams of multi-bit flip flop (MBFF) regions, in accordance with some embodiments.

FIGS. 3A-3B are corresponding cross-sections, in accordance with some embodiments.

FIGS. 4A-4B are corresponding schematic circuit diagrams, in accordance with some embodiments.

FIG. 5 is a flow diagram of a method of manufacturing a semiconductor device, in accordance with some embodiments.

FIG. 6 is a flow diagram of a method of operating an MBFF, in accordance with some embodiments.

FIGS. 7A-7B are corresponding flow diagrams of corresponding methods of manufacturing a semiconductor device, in accordance with some embodiments.

FIG. 8 is a block diagram of an electronic design automation (EDA) system in accordance with some embodiments.

FIG. 9 is a block diagram of an integrated circuit (IC) manufacturing system, and an IC manufacturing flow associated therewith, in accordance with some embodiments.

### DETAILED DESCRIPTION

The following disclosure discloses many different embodiments, or examples, for implementing different features of the subject matter. Examples of components, materials, values, steps, operations, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows include embodiments in which the first and second features are formed in direct contact, and further include embodiments in which additional features are formed between the first and second features, such that the first and second features are in indirect contact. In addition, the present disclosure repeats reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, are used herein for case of description to describe one element or feature's relationship to another element(s) or feature(s) as illustrated in the figures. The spatially relative terms are intended to encompass different orientations of the device in use or operation in addition to the orientation depicted in the figures. The apparatus is otherwise oriented (rotated 90 degrees or at other orientations) and the spatially relative descriptors used herein are likewise interpreted accordingly. In some embodiments, the term standard cell structure refers to a standardized building block included in a library of various standard cell structures. In some embodiments, various standard cell structures are selected from a library thereof and are used as components in a layout diagram representing a circuit.

In some embodiments, a semiconductor device includes single-bit flip-flop regions (SBFF regions) which comprise a multi-bit flip-flop (MBFF) region. The MBFF region has a two-dimensional floor plan represented by a grid including rows and at least a first column extending in corresponding first (e.g., parallel to the X-axis) and perpendicular second (e.g., parallel to the Y-axis) directions. Each SBFF region represents an intersection of a corresponding row and column. The SBFF regions are coupled in a daisy chain for which an output of a preceding one of the SBFF regions in the daisy chain is coupled to an input of a succeeding one of the SBFF regions in the daisy chain. Orientations of the SBFF regions relative to the X-axis (X-orientations) are arranged in an alternating pattern relative to the Y-axis so that a two-dimensional representation of a flow path of a data signal along the first column has a serpentine shape (serpentine-configured flow path). In some embodiments, relative to the Y-axis, each SBFF region has either a first type amongst the X-orientations (first X-orientation) or a reversed, second type amongst the X-orientations (second X-orientation) as follows: the first X-orientation has an input region of the SBFF at a first side of the column and an output region at a second side of the column; and the second X-orientation has the input region of the SBFF at the second side of the column and the output region of the SBFF at the first side of the column.

According to another approach, a counterpart MBFF region of a semiconductor device includes a counterpart column formed by stacking counterpart SBFF regions. According to the other approach, each SBFF region in the column according to the other approach has the same X-orientation, i.e., the input region of each SBFF region is at a first side of the column and the output region of each SBFF region is at a second side of the column. As part of insight which led the present inventors to develop at least some embodiments, the inventors recognized at least the following: a two-dimensional representation of a flow path of a data signal along the column according to the other approach has a sawtooth shape (sawtooth-configured flow path); and routing of the sawtooth pattern in the MBFF region according to the other approach increases routing congestion in a second layer of metallization (M_2nd layer) and a third layer of metallization (M_3rd layer), which diminishes routing opportunities in areas of the M_2nd and M_3rd layers that are above the counterpart MBFF region. By contrast, the serpentine-configured flow path of the MBFF according to at least some embodiments reduces routing congestion in the M_2nd layer and the M_3rd layer as compared to the sawtooth-configured flow path of the MBFF according to the other approach. Accordingly, the serpentine-configured flow path of the MBFF according to at least some embodiments increases routing opportunities in areas of the M_2nd and M_3rd layers that are above the MBFF region as compared to fewer opportunities for the sawtooth-configured flow path of the MBFF according to the other approach.

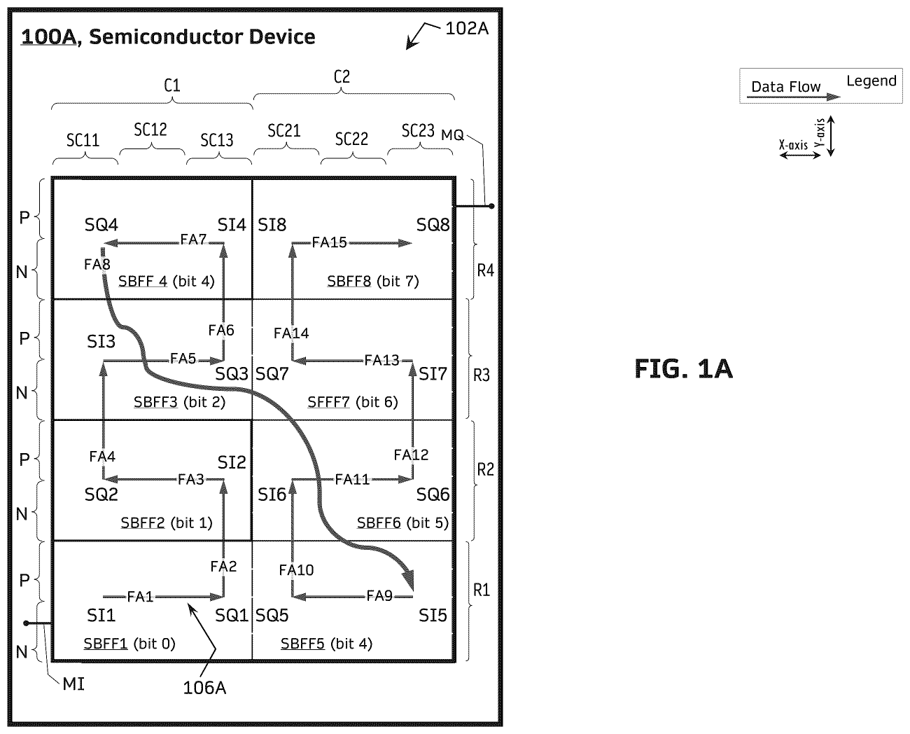

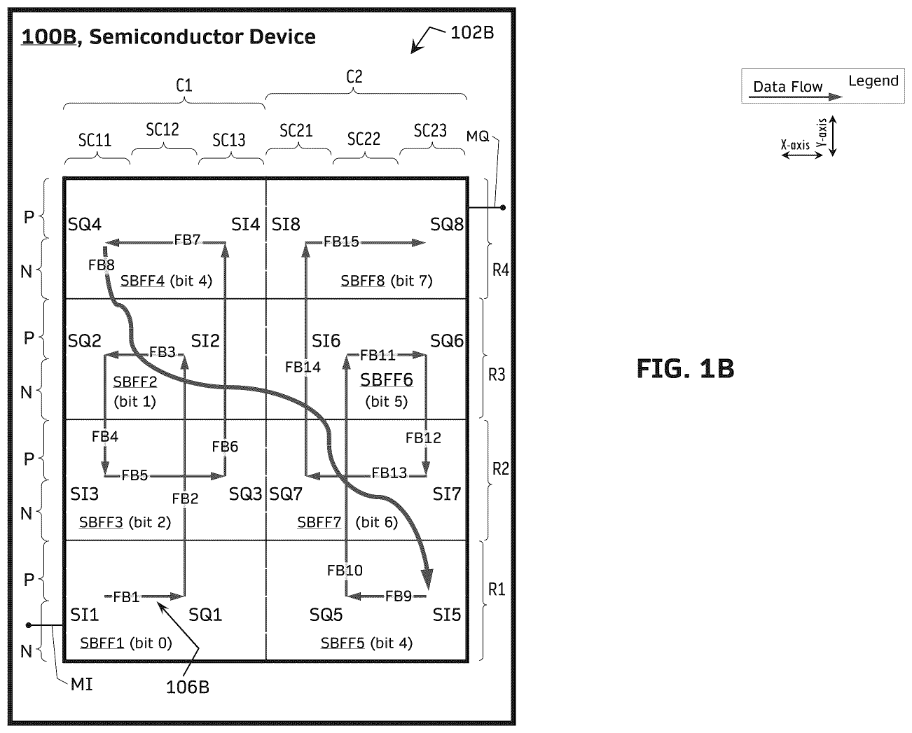

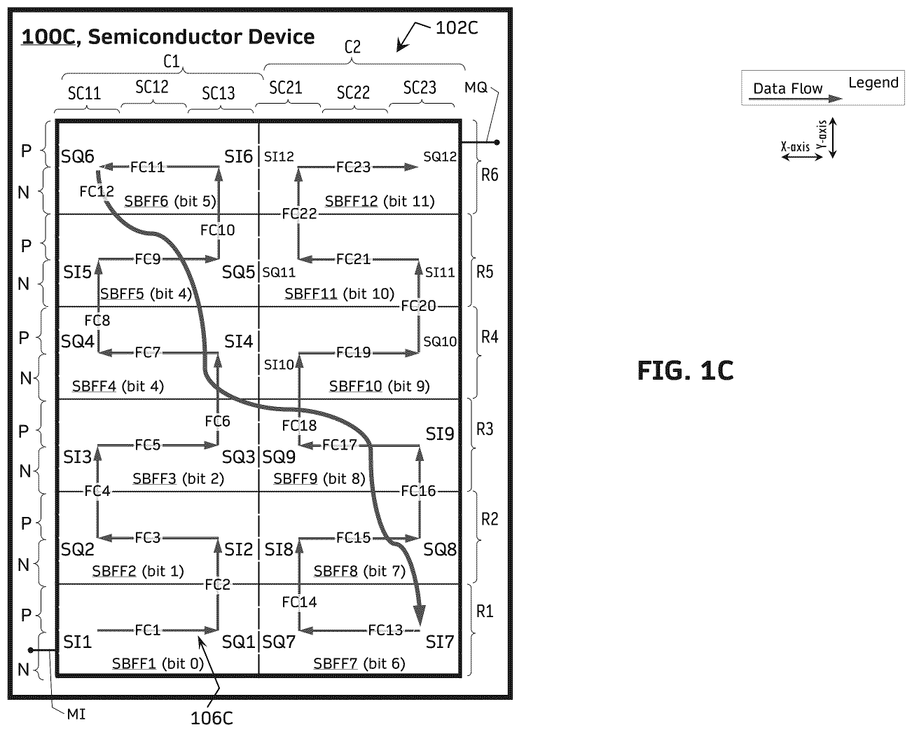

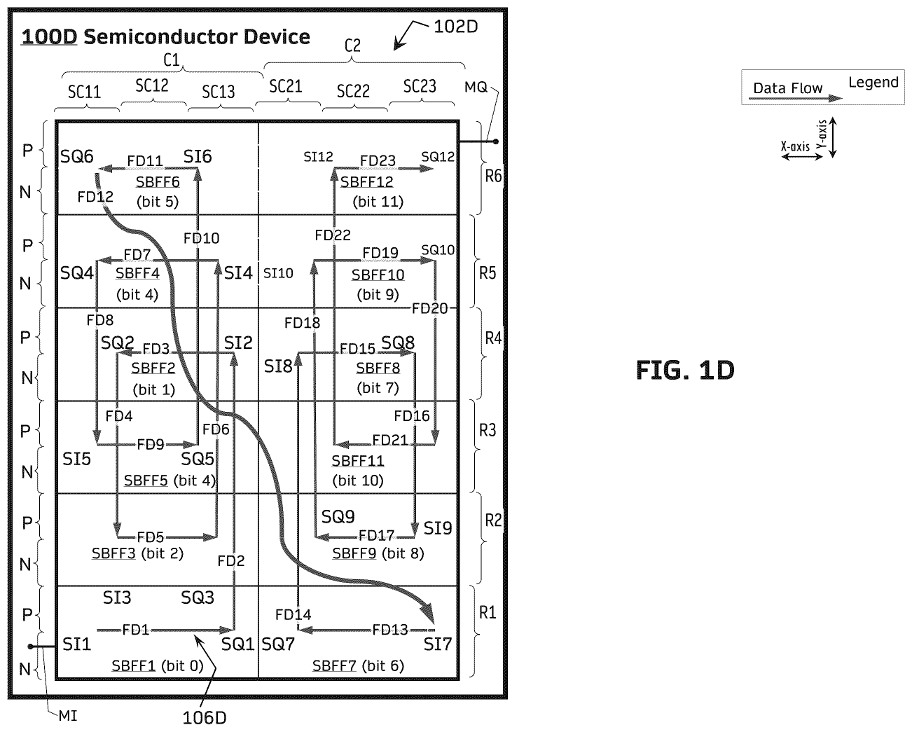

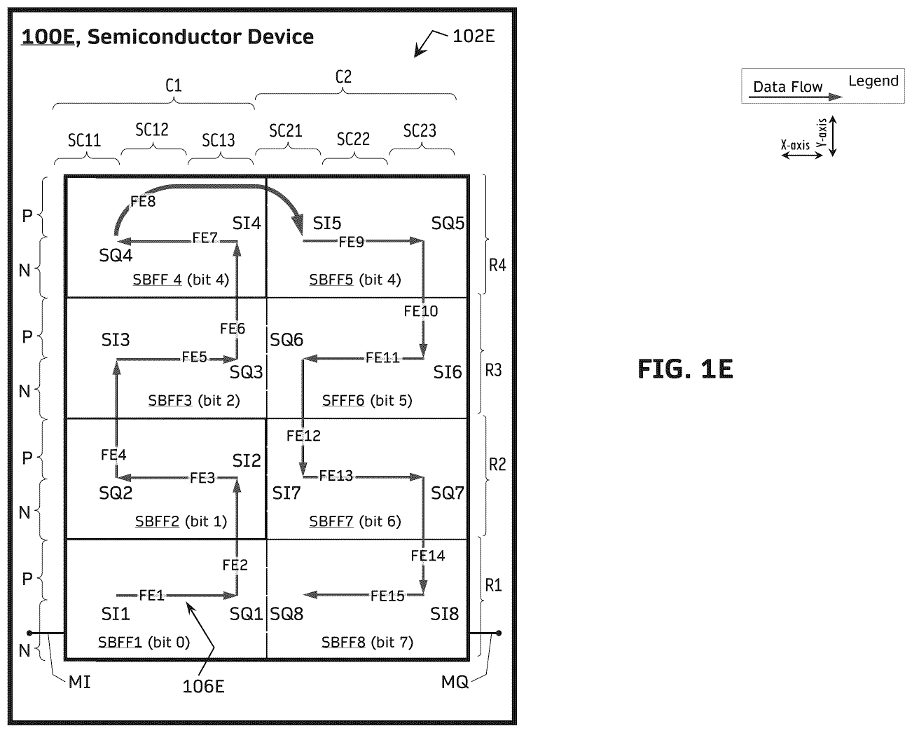

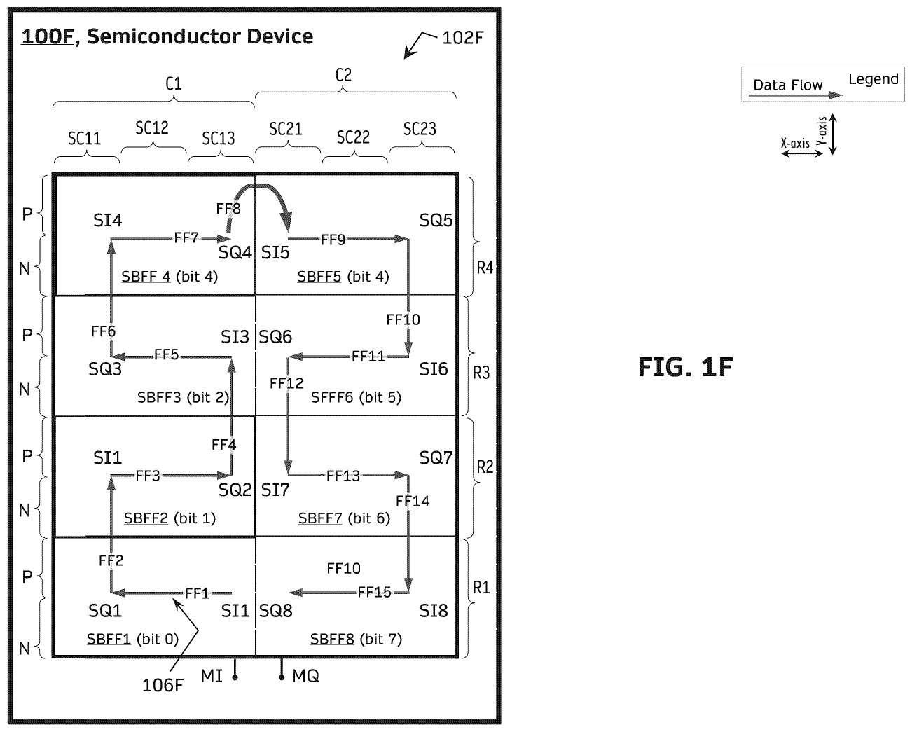

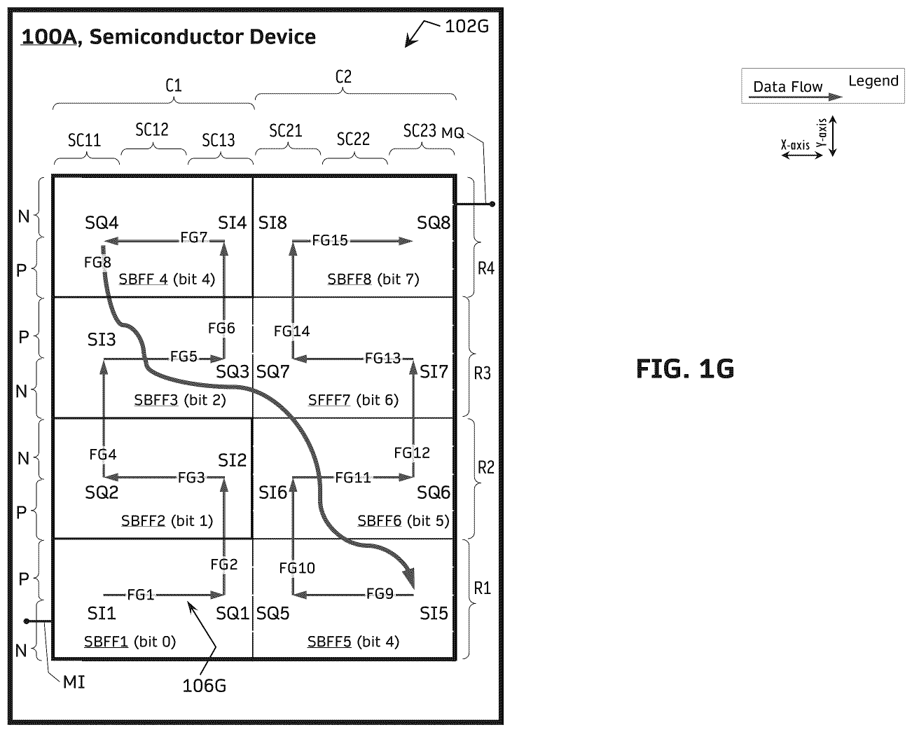

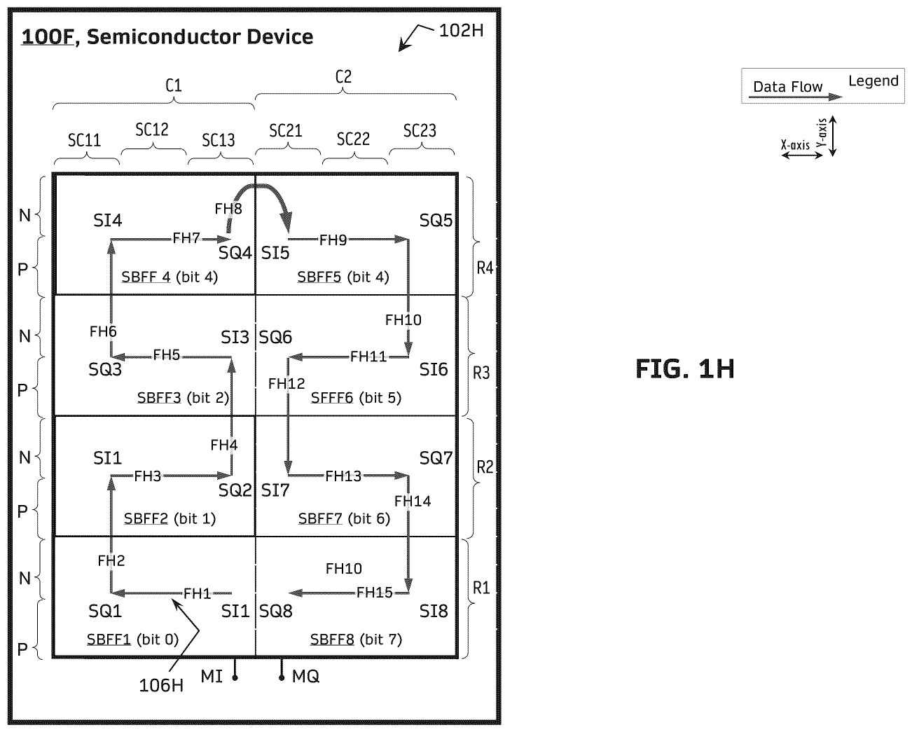

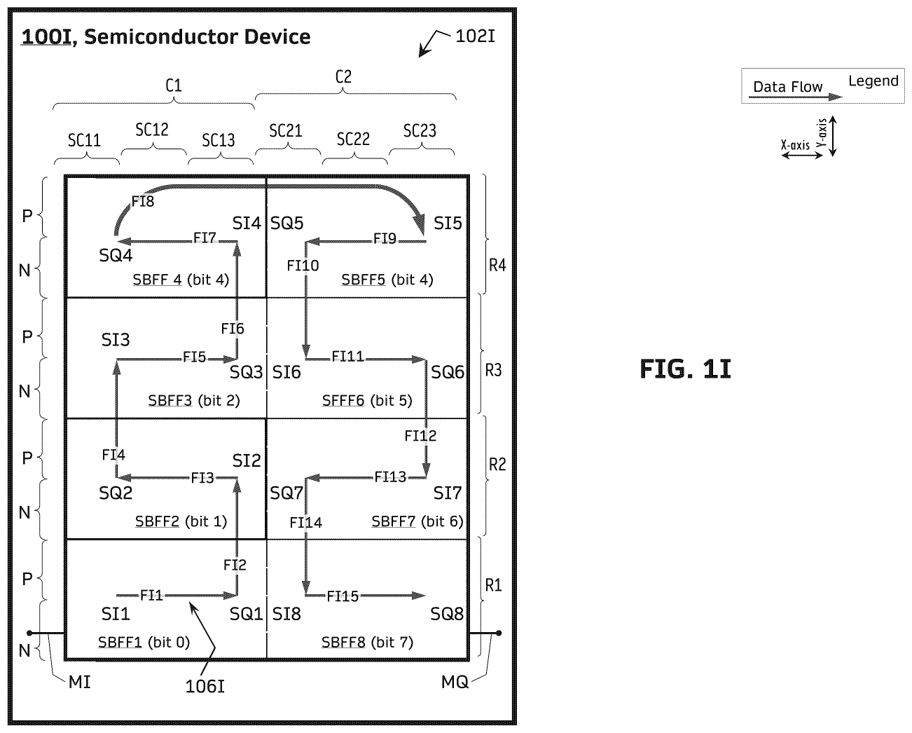

FIG. 1A is a block diagram of a semiconductor device 100A which includes a MBFF region 102A, in accordance with some embodiments.

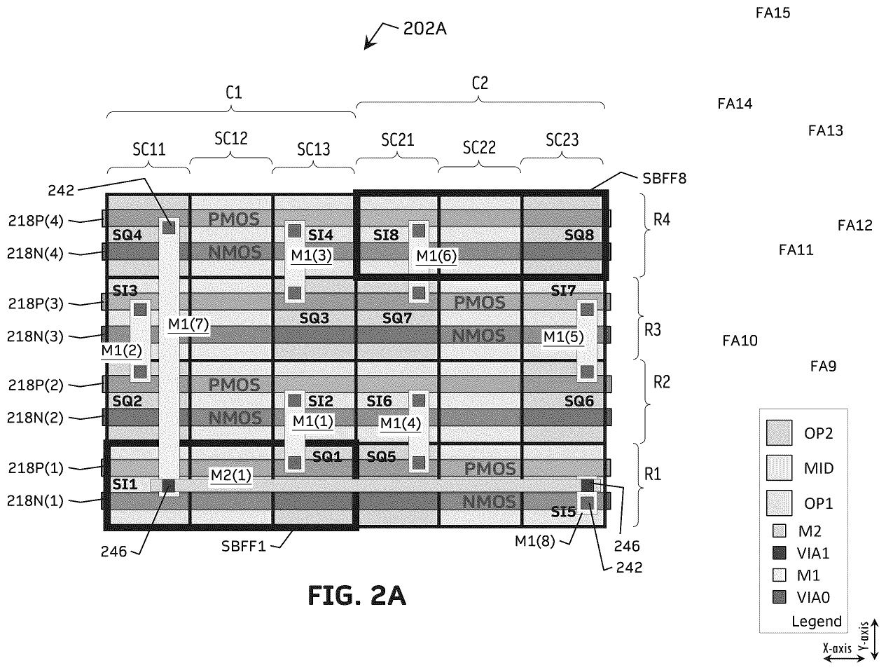

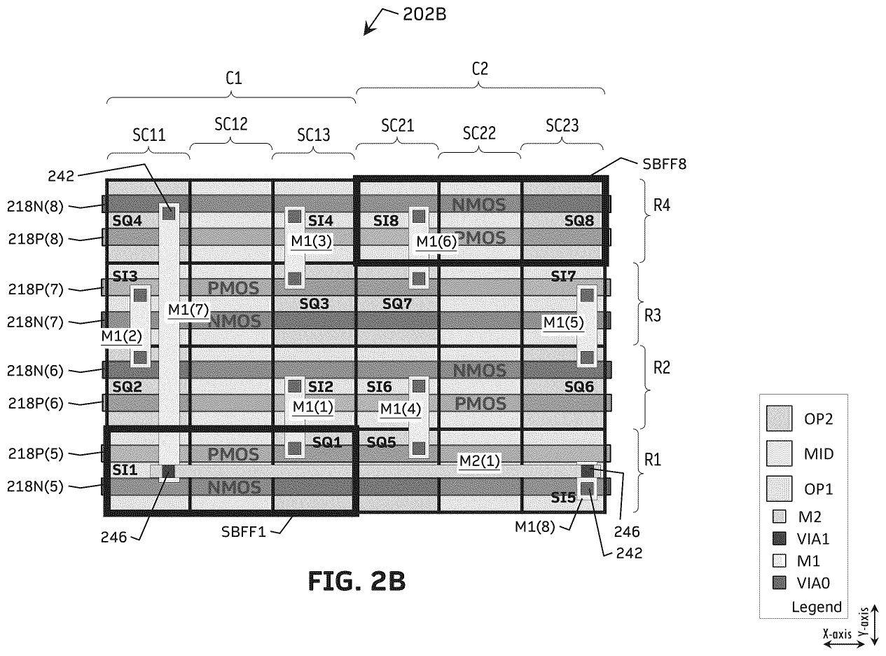

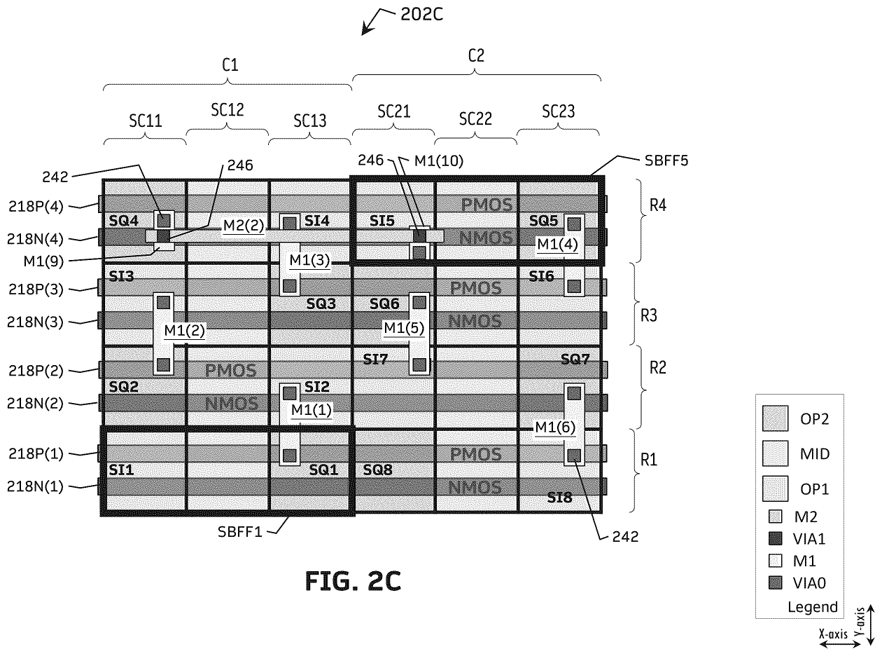

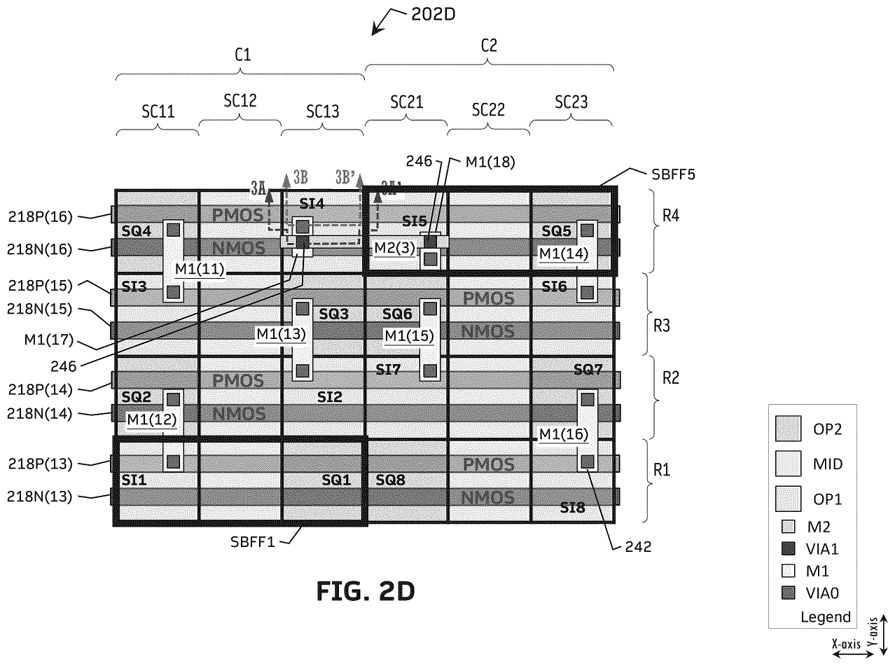

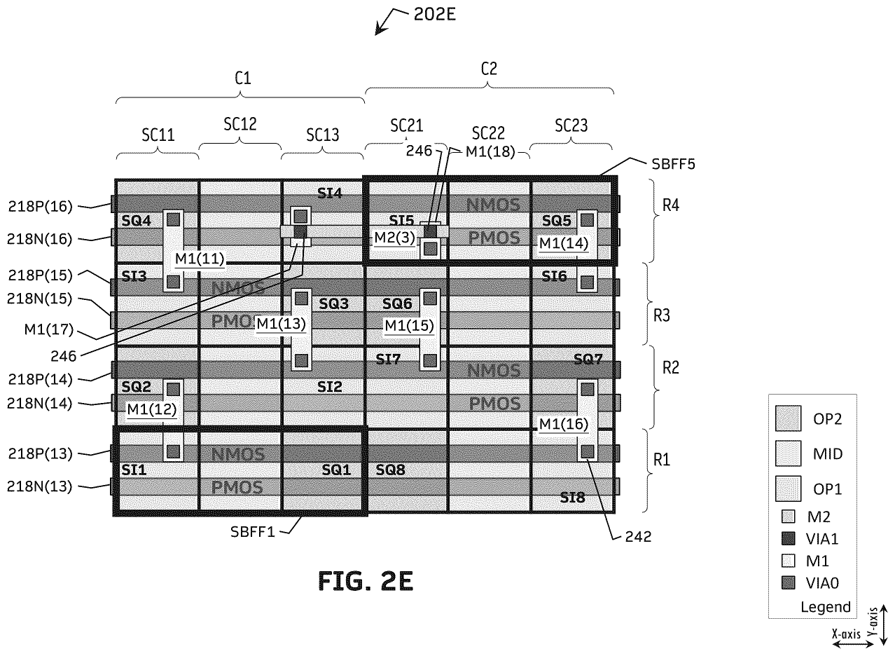

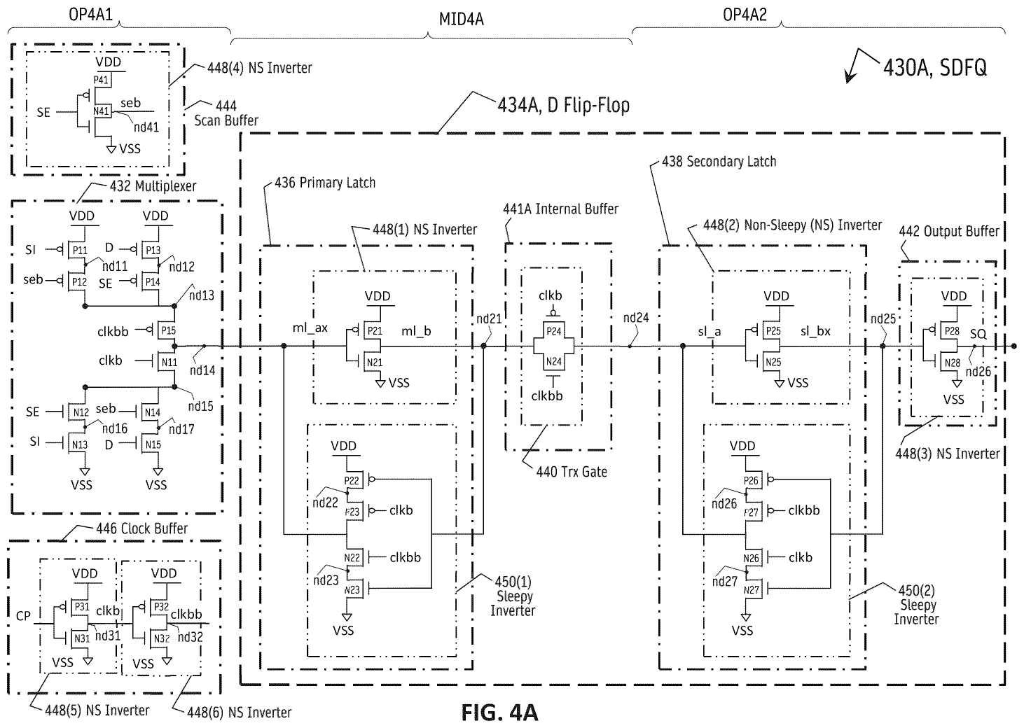

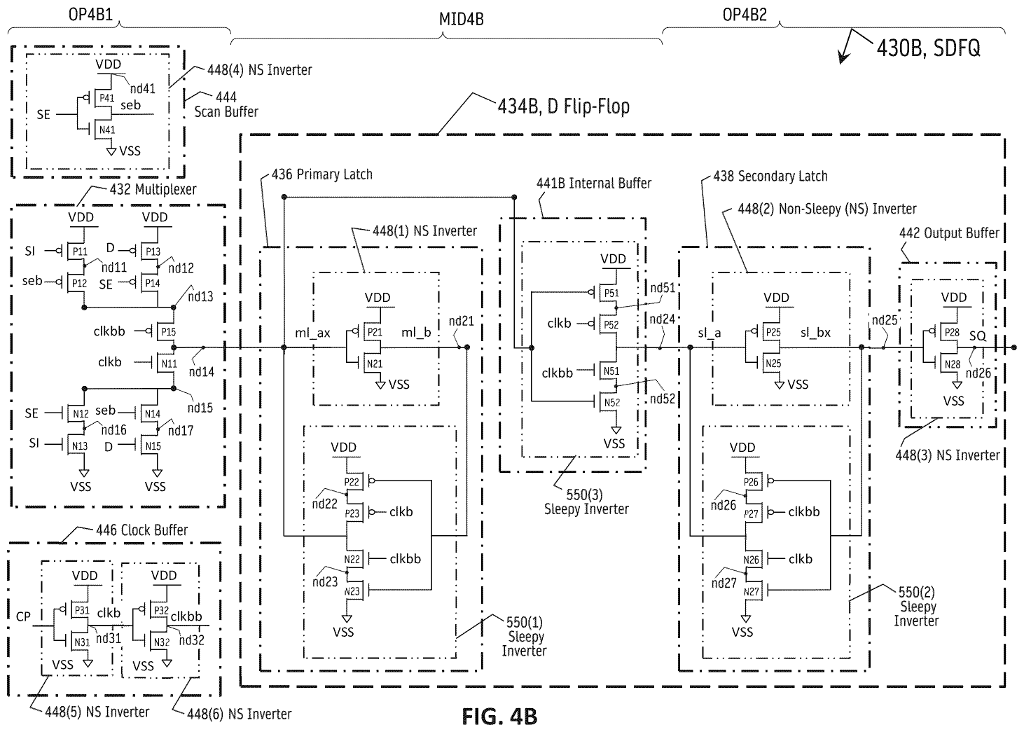

MBFF region 102A includes SBFF regions. More particularly, MBFF region 102A includes first to (N)th SBFF regions such that MBFF region 102A is an N-bit MBFF region, where N is a positive integer. The first to (Nth) SBFF regions represent single bits b(0) to b(N−1) of MBFF 102A such that MBFF 102A is an N-bit MBFF. In some embodiments, each of the first to (N)th SBFF regions of MBFF region 102A is a scan D FF (SDFQ). Examples of the SDFQ include SDFQ 430A of FIG. 4A. SDFQ 430B of FIG. 4B, or the like. FIG. 2A (discussed below) is a layout diagram of an MBFF region corresponding to MBFF region 102A.

Regarding FIG. 1A, for simplicity of illustration, FIG. 1A assumes that N=8 such that MBFF region 102A is an 8-bit MBFF that includes SBFF regions 1-8 (SBFF1-SBFF8). Region SBFF1 represents bit b(0). Region SBFF2 represents bit b(1). Region SBFF3 represents bit b(2). Region SBFF4 represents bit b(3). Region SBFF5 represents bit b(4). Region SBFF6 represents bit b(5). Region SBFF7 represents bit b(6). Region SBFF8 represents bit b(N−1), i.e., b(7). In some embodiments. N is a positive integer other than N=8.

In FIG. 1A. MBFF region 102A has a two-dimensional floor plan represented by a grid including rows R1-R4 and columns extending in corresponding first (e.g., parallel to the X-axis) and perpendicular second (e.g., parallel to the Y-axis) directions. In general, the number of rows in MBFF 102A is N/2. Recalling that FIG. 1A assumes that N=8, accordingly FIG. 1A shows MBFF 102A as including four rows, R1-R4. In some embodiments, the first and second directions are perpendicular albeit something other than directions which are correspondingly parallel to the X-axis and the Y-axis. Each SBFF region represents an intersection of a corresponding row and column. The columns include a first column C1 and a second column C2. In some embodiments, the columns are referred to as legs.

Regions SBFF1-SBFF8 include corresponding inputs SI1-SI8 and corresponding outputs SQ1-SQ8. An input of MBFF region 102A is represented by input SI1 of region SBFF1. An output of MBFF region 102A is represented by output SQ8 of region SBFF8.

Regions SBFF1-SBFF8 are daisy-chain coupled, i.e., are coupled in a daisy chain. A flow path 106A is a two-dimensional representation of a flow path of a data signal through the daisy chain, i.e., through MBFF region 102A. Flow path 106A is comprised of path fragments FA1-FA15, where each of path fragments FA1-FA15 are shown as an arrow in FIG. 1A.

In each of the SBFF regions of FIG. 1A, internal circuitry (FIGS. 4A-4B, or the like) couples the input of the SBFF region to the output of the SBFF region. Such intra-SBFF couplings are shown as path fragments FA1, FA3, FA5, FA7, FA9, FA11, FA13 and FA15 in FIG. 1A, each of which is parallel to the X-axis.

Input SI1 of region SBFF1 is coupled to output SQ1 of region SBFF1 as represented by arrow FA1. Input SI2 of region SBFF2 is coupled to output SQ2 of region SBFF2 as represented by arrow FA3. Input SI3 of region SBFF3 is coupled to output SQ3 of region SBFF3 as represented by arrow FA5. Input SI4 of region SBFF4 is coupled to output SQ4 of region SBFF4 as represented by arrow FA7. Input SI5 of region SBFF5 is coupled to output SQ5 of region SBFF1 as represented by arrow FA9. Input SI6 of region SBFF6 is coupled to output SQ6 of region SBFF6 as represented by arrow FA11. Input SI7 of region SBFF7 is coupled to output SQ7 of region SBFF7 as represented by arrow FA13. Input SI8 of region SBFF8 is coupled to output SQ8 of region SBFF8 as represented by arrow FA15.

In FIG. 1A, the daisy chain couples an output of a preceding one of the SBFF regions in the daisy chain is coupled to an input of a succeeding one of the SBFF regions in the daisy chain. Such inter-SBFF couplings are shown as path fragments FA2, FA4, FA6, FA8, FA10, FA12 and FA14 in FIG. 1A, each of which is parallel to the Y-axis.

Input SI2 of region SBFF2 is coupled to output SQ1 of region SBFF1 as represented by arrow FA2. Input SI3 of region SBFF3 is coupled to output SQ2 of region SBFF2 as shown by arrow FA4. Input S14 of region SBFF4 is coupled to output SQ3 of region SBFF3 as shown by arrow FA6. Input SI5 of region SBFF5 is coupled to output SQ4 of region SBFF4 as shown by arrow FA8 Input SI6 of region SBFF6 is coupled to output SQ5 of region SBFF5 as shown by arrow FA10. Input SI7 of region SBFF7 is coupled to output SQ6 of region SBFF6 as shown by arrow FA12. Input SI8 of region SBFF8 is coupled to output SQ7 of region SBFF7 as shown by arrow FA14.

Each of path fragments FA2, FA4, FA6, FA10, FA12 and FA14 extends upwardly from a first row into an immediately adjacent (first-adjacent) second row. Each of path fragments FA2 and FA10 extends from row R1 into row R2. Each of path fragments FA4 and FA12 extends from row R2 into row R3. Each of path fragments FA6 and FA14 extends from row R3 into row R4.

In FIG. 1A, each of first column C1 and second column C2 is arranged as a stack of SBFF regions relative to the Y-axis. Relative to the Y-axis, in first column C1, region SBFF2 is stacked on region SBFF1. Region SBFF3 is stacked on region SBFF2. Region SBFF4 is stacked on region SBFF3. As such, in first column C1, bit b(0) is at the bottom of the stack and bit b(3) is at the top of the stack relative the Y-axis such that the bit sequence from bottom to top is b(0)→b(1)→b(2)→b(3). In second column C2, bit b(4) is at the bottom of the stack and bit b(7) is at the top of the stack relative the Y-axis such that the bit sequence from bottom to top is b(4)→b(5)→b(6)→b(7).

Each of rows R1-R4 includes a corresponding single SBFF region in first column C1 and corresponding single SBFF region in second column C2. In general, first column C1 includes first to (i+1)th SBFF regions representing bits b(0) to b(i), and second column C2 includes (i+2)th to (N)th SBFF regions representing bits b(i+1) to b(N−1), where i is a positive integer and i<N. Recalling that FIG. 1A assumes N=4, FIG. 1A shows first column C1 as including regions SBFF1-SBFF4 representing bits b(0)-b(3) and second column C2 as including regions SBFF5-SBFF8 representing bits b(4)-b(7).

In FIG. 1A, each of the SBFF regions includes at least one first active region (AR) (FIG. 2A) and at least one second AR (FIG. 2A). The first AR has a first type of conductivity and the second AR has a different second type of conductivity. In FIG. 1A, the following is assumed: the first type of conductivity is a positive-type (P-type) conductivity, as indicated by a curly-bracket and the uppercase letter P; and the second type of conductivity is a negative-type (N-type) of conductivity, as indicated by a curly-bracket and an uppercase letter N. In some embodiments, the first type of conductivity is a negative-type (N-type) of conductivity and that the second type of conductivity is a positive-type (P-type) conductivity.

In general, relative to the Y-axis, each of the SBFF regions in MBFF 102A has either a first orientation or second orientation (Y-orientation). The first Y-orientation has the first AR stacked on the second AR. The second Y-orientation has the second AR stacked on the first AR (PMOS). In FIG. 1A, each of rows R1-R4 has the first Y-orientation. In some embodiments, some (e.g., FIG. 1G, or the like) or all of the rows of the MBFF region have the second Y-orientation.

In general, relative to the X-axis, each of the SBFF regions in MBFF 102A has either a first orientation or second orientation (X-orientation). The first X-orientation has an input region of the SBFF at a first side of the column and an output region at a second side of the column. The second X-orientation has the input region of the SBFF at the second side of the column and the output region of the SBFF at the first side of the column. In FIG. 1A, the first side of each of first column C1 and second column C2 is assumed to be the left side and the second side of each of first column C1 and second column C2 is assumed to be the right side. In some embodiments, the first and second sides of the columns are opposite to that which is assumed in FIG. 1A.

In FIG. 1A, for simplicity of illustration, it is assumed that each column includes three sub-columns. First column C1 includes three sub-columns SC11, SC12 and SC13, where sub-column SC12 is between sub-columns SC11 and SC13. Second column C2 includes three sub-columns SC21, SC22 and SC23, where sub-column SC22 is between sub-columns SC21 and SC23. In general, each of first column C1 and second column C2 includes at least two sub-columns. In some embodiments, each of first column C1 and second column C2 includes four or more sub-columns.

In general, the X-orientations of the SBFF regions are as follows. The first X-orientation of each SBFF region has the input region substantially in the first sub-column (SC11 or SC21) and the output region substantially in the third sub-column (SC13 or SC23). The second X-orientation of each SBFF region has the input region substantially in the third sub-column (SC13 or SC23) and the output region of the SBFF substantially in the first sub-column (SC11 or SC21).

In some embodiments (not shown), the X-orientations of the SBFF regions are as follows. The first X-orientation of each SBFF region has the input region substantially in the third sub-column (SC13 or SC23) and the output region substantially in the first sub-column (SC11 or SC21). The second X-orientation of each SBFF region has the input region substantially in the first sub-column (SC13 or SC23) and the output region of the SBFF substantially in the third sub-column (SC11 or SC21).

In FIG. 1A, the X-orientations of the SBFF regions are as follows. Each of regions SBFF1. SBFF3, SBFF6 and SBFF8 has the first X-orientation. Regarding region SBFF1, input SI1 is in first column SC11 and output SQ1 is in third sub-column SC13. Regarding region SBFF3, input SI3 is in sub-column SC11 and output SQ3 is in sub-column SC13. Regarding region SBFF6, input SI6 is in sub-column SC21 and output SQ6 is in sub-column SC23. Regarding region SBFF8, input SI8 is in sub-column SC21 and output SQ8 is in sub-column SC23.

Each of regions SBFF2, SBFF4, SBFF5 and SBFF7 has the second X-orientation. Regarding region SBFF2, input SI2 is in third column SC13 and output SQ2 is in first sub-column SC11. Regarding region SBFF4, input S14 is in sub-column SC13 and output SQ3 is in sub-column SC11. Regarding region SBFF5, input SI5 is in sub-column SC23 and output SQ5 is in sub-column SC21. Regarding region SBFF7, input SI7 is in sub-column SC23 and output SQ7 is in sub-column SC21.

In FIG. 1A. X-orientations of the SBFF regions relative to the X-axis are arranged in an alternating pattern relative to the Y-axis so that the portion of flow path 106A along each of each of first column C1 and second column C2 has a corresponding serpentine shape. More particularly, the serpentine shape of the portion of flow path 106A along each of first column C1 and second column C2 is a non-self-overlapping serpentine shape relative to the Y-axis. The portion of flow path 106A along first column C1 does not overlap itself, i.e., is non-self-overlapping, relative to the Y-axis. The portion of flow path 106A along second column C2 does not overlap itself. i.e., is non-self-overlapping. In some embodiments of the MBFF, by contrast, the portion of the flow path along each of first column C1 and second column C2 is a self-overlapping serpentine shape (e.g., FIGS. 1B, 1D, or the like).

In FIG. 1A, by coupling output SQ4 of region SBFF4 to input SI5 of region SBFF5, path fragment FA8 couples first column C1 to second column C2. Path fragment FA8 extends from row R4 into row R1. In some embodiments, fragment FA8 is described as a diagonal fragment because it couples the top of first column C1. i.e., output SQ4 of region SBFF4, to the bottom of second column C2, i.e., to input SI5 of region SBFF5. In some embodiments, the two-dimensional representation of an overall flow path of a data signal in MBFF 102A is described as resembling an uppercase letter N. i.e., as being N-shaped.

According to another approach, a counterpart MBFF region of a semiconductor device includes a counterpart column represented by a stack of SBFF regions, the column including first, second and third sub-columns that are counterparts to sub-columns SC11-SC13 or SC21-SC23 of FIG. 1A. According to the other approach, each SBFF region in the column according to the other approach has the same X-orientation: the input region of each SBFF region is in the first sub-column and the output region of each SBFF region is in the third sub-column; or the input region of each SBFF region is in the third sub-column and the output region of each SBFF region is in the first sub-column. As part of insight which led the present inventors to develop at least some embodiments, the inventors recognized at least the following: a two-dimensional representation of a flow path of a data signal along the column according to the other approach has a sawtooth shape (sawtooth-configured flow path); and path fragments of the sawtooth shape that extend in the direction of the Y-axis are either all located either in the first sub-column or are all located in the third sub-column. Also as part of insight which led the present inventors to develop at least some embodiments, the inventors further recognized at least that routing of the sawtooth pattern in the MBFF region according to the other approach increases routing congestion in a second layer of metallization (M_2nd layer) and a third layer of metallization (M_3rd layer), which diminishes routing opportunities in areas of the M_2nd and M_3rd layers that are above the counterpart MBFF region. By contrast, serpentine-configured flow path 106A of MBFF 102A reduces routing congestion in the M_2nd layer (FIGS. 2A-2E) and the M_3rd layer (FIGS. 2A-2E) as compared to the sawtooth-configured flow path of the MBFF according to the other approach. Accordingly, serpentine-configured flow path 106A of MBFF 102A increases routing opportunities in areas of the M_2nd and M_3rd layers that are above the MBFF region as compared to fewer opportunities for the sawtooth-configured flow path of the MBFF according to the other approach.

FIG. 1B is a block diagram of a semiconductor device 100B which includes an MBFF region 102B, in accordance with some embodiments.

MBFF 102B of FIG. 1B is similar to MBFF 102A of FIG. 1A. For brevity, the discussion will focus on differences of MBFF 102B as compared to MBFF 102A rather than on similarities. Likewise, regarding other instances in which a second figure is similar to a first figure, the discussion will focus on differences of the second figure with respect to the first figure, for brevity.

In FIG. 1B, the stacking order of SBFF regions in each of first column C1 and second column C2 is different than in FIG. 1A. Relative to the Y-axis, in first column C1, region SBFF3 is stacked on region SBFF1. Region SBFF2 is stacked on region SBFF3. Region SBFF4 is stacked on region SBFF2. Relative to the Y-axis, in second column C2, region SBFF7 is stacked on region SBFF5. Region SBFF6 is stacked on region SBFF7. Region SBFF 8 is stacked on region SBFF6.

Despite the different stacking order in first column C1 of FIG. 1B, bit b(0) is at the bottom of the stack and bit b(3) is at the top of the stack relative the Y-axis such that the bit sequence remains b(0)→b(1)→b(2)→b(3). Despite the different stacking order in second column C2, bit b(4) is at the bottom of the stack and bit b(7) is at the top of the stack relative the Y-axis such that the bit sequence remains b(4)→b(5)→b(6)→b(7).

The different stacking order of SBFF regions in FIG. 1B results in the portion of flow path 106B along each of each of first column C1 and second column C2 having a serpentine shape which also is self-overlapping relative to the Y-axis. The portion of flow path 106B along first column C1 overlaps itself, i.e., is self-overlapping relative to the Y-axis. The portion of flow path 106B along second column C2 overlaps itself, i.e., is self-overlapping relative to the Y-axis. In some embodiments of the MBFF, by contrast, the portion of the flow path along each of first column C1 and second column C2 is a non-self-overlapping serpentine shape (e.g., FIGS. 1A, 1C. 1E-1H, or the like).

Flow path 106B of a data signal in MBFF 102B is comprised of path fragments FB1-FB15. Each of path fragments FB4 and FB12 extends downwardly from a first row into an immediately adjacent (first-adjacent) second row. More particularly, each of path fragments FB4 and FB12 extends downwardly from row R3 into row R2. Each of path fragments FB2, FB6, FB10 and FB14 extends upwardly from a first row into a second-adjacent second row. Each of path fragments FB2 and FB10 extends upwardly from row R1 into row R3. Each of path fragments FB6 and FB14 extends upwardly from row R2 into row R4.

Serpentine-configured flow path 106B of MBFF 102B has advantages over a counterpart sawtooth-configured flow path according to the other approach that are similar to the advantages that serpentine-configured flow path 106A of MBFF 102A has over the sawtooth-configured flow path of the counterpart thereto according to the other approach.

In first column C1 of FIG. 1B, relative to the Y-axis, path fragments FB2, FB4 and FB6 at least partially overlap each other. In first column C1 of FIG. 1B, path fragment FB4 is fully overlapped by each of path fragments FB2 and FB6. In second column C2 of FIG. 1B, relative to the Y-axis, path fragments FB10, FB12 and FB14 at least partially overlap each other. In second column C2 of FIG. 1B, path fragment FB12 is fully overlapped by each of path fragments FB10 and FB14.

In FIG. 1B, the overlapping serpentine shape of the portion of flow path 106B along each of first column C1 and second column C2 is a self-intersecting and overlapping serpentine shape. The portion of flow path 106B along first column C1 intersects with itself, i.e., is self-intersecting. The portion of flow path 106B along second column C2 intersects with itself, i.e., is self-intersecting. In some embodiments of the MBFF, by contrast, the portion of the flow path along each of first column C1 and second column C2 is a non-self-intersecting albeit overlapping serpentine shape (not shown).

In FIG. 1B, each of rows R1-R4 has the first Y-orientation. In some embodiments (not shown), some or all of the rows of MBFF region 102B have the second Y-orientation.

In FIG. 1B, by coupling output SQ4 of region SBFF4 to input SI5 of region SBFF5, path fragment FB8 couples first column C1 to second column C2. Path fragment FB8 extends from row R4 into row R1. In some embodiments, fragment FB8 is described as a diagonal fragment because it couples the top of first column C1, i.e., output SQ4 of region SBFF4, to the bottom of second column C2, i.e., to input SI5 of region SBFF5. In some embodiments, the two-dimensional representation of an overall flow path of a data signal in MBFF 102B is described as resembling an uppercase letter N. i.e., as being N-shaped.

FIG. 1C is a block diagram of a semiconductor device 100C which includes an MBFF region 102C, in accordance with some embodiments.

MBFF 102C of FIG. 1C is similar to MBFF 102A of FIG. 1A.

MBFF 102C includes six rows, R1-R6, whereas MBFF 102A includes four rows, R1-R4. MBFF 102C is a 12-bit MBFF, whereas MBFF 102A is an 8-bit MBFF. First column C1 of MBFF 102C includes regions SBFF1-SBFF6 representing bits b(0) to b(5). Second column C2 of MBFF 102C includes regions SBFF7-SBFF12 representing bits b(6) to b(11). Each of rows R1-R6 has the first Y-orientation. In some embodiments (not shown), some or all of the rows of MBFF region 102C have the second Y-orientation.

In FIG. 1C, regions SBFF1-SBFF12 are daisy-chain coupled. A flow path 106C is a two-dimensional representation of a flow path of a data signal through the daisy chain, i.e., through MBFF region 102C. Flow path 106C is comprised of path fragments FC1-FC23, where each of path fragments FC1-FC23 are shown as arrows in FIG. 1C.

The intra-SBFF couplings are shown as path fragments FC1, FC3, FC5, FC7, FC9, FC11, FC13, FC15, FC17, FC19, FC21 and FC23 in FIG. 1C, each of which is parallel to the X-axis.

Input SI1 of region SBFF1 is coupled to output SQ1 of region SBFF1 as represented by arrow FC1. Input S12 of region SBFF2 is coupled to output SQ2 of region SBFF2 as represented by arrow FC3. Input SI3 of region SBFF3 is coupled to output SQ3 of region SBFF3 as represented by arrow FC5. Input SI4 of region SBFF4 is coupled to output SQ4 of region SBFF4 as represented by arrow FC7. Input SI5 of region SBFF5 is coupled to output SQ5 of region SBFF1 as represented by arrow FC9. Input SI6 of region SBFF6 is coupled to output SQ6 of region SBFF6 as represented by arrow FC11. Input SI7 of region SBFF7 is coupled to output SQ7 of region SBFF7 as represented by arrow FC13. Input SI8 of region SBFF8 is coupled to output SQ8 of region SBFF8 as represented by arrow FC15. Input S19 of region SBFF9 is coupled to output SQ9 of region SBFF9 as represented by arrow FC17. Input SI10 of region SBFF10 is coupled to output SQ10 of region SBFF10 as represented by arrow FC19. Input SI11 of region SBFF11 is coupled to output SQ11 of region SBFF11 as represented by arrow FC21. Input SI2 of region SBFF12 is coupled to output SQ12 of region SBFF12 as represented by arrow FC23.

The inter-SBFF couplings are shown as path fragments FC2, FC4, FC6, FC8, FC10, FC12, FC14, FC16, FC18, FC20 and FC22 in FIG. 1C, each of which is parallel to the Y-axis.

Input SI2 of region SBFF2 is coupled to output SQ1 of region SBFF1 as represented by arrow FC2. Input SI3 of region SBFF3 is coupled to output SQ2 of region SBFF2 as shown by arrow FC4. Input SI4 of region SBFF4 is coupled to output SQ3 of region SBFF3 as shown by arrow FC6. Input SI5 of region SBFF5 is coupled to output SQ4 of region SBFF4 as shown by arrow FC8 Input SI6 of region SBFF6 is coupled to output SQ5 of region SBFF5 as shown by arrow FC10. Input SI7 of region SBFF7 is coupled to output SQ6 of region SBFF6 as shown by arrow FC12. Input S18 of region SBFF8 is coupled to output SQ7 of region SBFF7 as shown by arrow FC14. Input S19 of region SBFF9 is coupled to output SQ8 of region SBFF8 as shown by arrow FC16. Input SI10 of region SBFF10 is coupled to output SQ9 of region SBFF9 as shown by arrow FC18. Input SI11 of region SBFF11 is coupled to output SQ10 of region SBFF10 as shown by arrow FC20. Input SI12 of region SBFF12 is coupled to output SQ11 of region SBFF11 as shown by arrow FC22.

In FIG. 1C, by coupling output SQ6 of region SBFF6 to input SI7 of region SBFF7, path fragment FC12 couples first column C1 to second column C2. Path fragment FC12 extends from row R6 into row R1.

In FIG. 1C, X-orientations of the SBFF regions relative to the X-axis are arranged in an alternating pattern relative to the Y-axis so that the portion of flow path 106A along each of each of first column C1 and second column C2 has a corresponding serpentine shape. More particularly, the serpentine shape of the portion of flow path 106C along each of first column C1 and second column C2 is a non-self-overlapping serpentine shape. Serpentine-configured flow path 106C of MBFF 102C has advantages over a counterpart sawtooth-configured flow path according to the other approach that are similar to the advantages that serpentine-configured flow path 106A of MBFF 102A has over the sawtooth-configured flow path of the counterpart thereto according to the other approach.

FIG. 1D is a block diagram of a semiconductor device 100D which includes an MBFF region 102D, in accordance with some embodiments.

MBFF 102D of FIG. 1D is similar to MBFF 102B of FIG. 1B.

MBFF 102D includes six rows, R1-R6, whereas MBFF 102B includes four rows, R1-R4. MBFF 102D is a 12-bit MBFF, whereas MBFF 102B is an 8-bit MBFF. First column D1 of MBFF 102D includes regions SBFF1-SBFF6 representing bits b(0) to b(5). Second column D2 of MBFF 102D includes regions SBFF7-SBFF12 representing bits b(6) to b(11). Each of rows R1-R6 has the first Y-orientation. In some embodiments (not shown), some or all of the rows of MBFF region 102D have the second Y-orientation.

In FIG. 1D, regions SBFF1-SBFF12 are daisy-chain coupled, i.e., are coupled in a daisy chain. B flow path 106D is a two-dimensional representation of a flow path of a data signal through the daisy chain, i.e., through MBFF region 102D. Flow path 106D is comprised of path fragments FD1-FD23, where each of path fragments FD1-FD23 are shown as arrows in FIG. 1D.

The intra-SBFF couplings are shown as path fragments FD1, FD3, FD5, FD7, FD9, FD11, FD13, FD15, FD17, FD19, FD21 and FD23 in FIG. 1D, each of which is parallel to the X-axis.

Input SI1 of region SBFF1 is coupled to output SQ1 of region SBFF1 as represented by arrow FD1. Input S12 of region SBFF2 is coupled to output SQ2 of region SBFF2 as represented by arrow FD3. Input SI3 of region SBFF3 is coupled to output SQ3 of region SBFF3 as represented by arrow FD5. Input SI4 of region SBFF4 is coupled to output SQ4 of region SBFF4 as represented by arrow FD7. Input SI5 of region SBFF5 is coupled to output SQ5 of region SBFF1 as represented by arrow FD9. Input SI6 of region SBFF6 is coupled to output SQ6 of region SBFF6 as represented by arrow FD11. Input SI7 of region SBFF7 is coupled to output SQ7 of region SBFF7 as represented by arrow FD13. Input SI8 of region SBFF8 is coupled to output SQ8 of region SBFF8 as represented by arrow FD15. Input SI9 of region SBFF9 is coupled to output SQ9 of region SBFF9 as represented by arrow FD17. Input SI10 of region SBFF10 is coupled to output SQ10 of region SBFF10 as represented by arrow FD19. Input SI11 of region SBFF11 is coupled to output SQ11 of region SBFF11 as represented by arrow FD21. Input SI2 of region SBFF12 is coupled to output SQ12 of region SBFF12 as represented by arrow FD23.

The inter-SBFF couplings are shown as path fragments FD2, FD4, FD6, FD8, FD10, FD12, FD14, FD16, FD18, FD20 and FD22 in FIG. 1D, each of which is parallel to the Y-axis.

Input SI2 of region SBFF2 is coupled to output SQ1 of region SBFF1 as represented by arrow FD2. Input SI3 of region SBFF3 is coupled to output SQ2 of region SBFF2 as shown by arrow FD4. Input SI4 of region SBFF4 is coupled to output SQ3 of region SBFF3 as shown by arrow FD6. Input SI5 of region SBFF5 is coupled to output SQ4 of region SBFF4 as shown by arrow FD8 Input SI6 of region SBFF6 is coupled to output SQ5 of region SBFF5 as shown by arrow FD10. Input SI7 of region SBFF7 is coupled to output SQ6 of region SBFF6 as shown by arrow FD12. Input SI8 of region SBFF8 is coupled to output SQ7 of region SBFF7 as shown by arrow FD14. Input S19 of region SBFF9 is coupled to output SQ8 of region SBFF8 as shown by arrow FD16. Input SI10 of region SBFF10 is coupled to output SQ9 of region SBFF9 as shown by arrow FD18. Input SI11 of region SBFF11 is coupled to output SQ10 of region SBFF10 as shown by arrow FD20. Input SI12 of region SBFF12 is coupled to output SQ11 of region SBFF11 as shown by arrow FD22.

In FIG. 1D, by coupling output SQ6 of region SBFF6 to input SI7 of region SBFF7, path fragment FD12 couples first column D1 to second column D2. Path fragment FD12 extends from row R6 into row R1.

In FIG. 1D. X-orientations of the SBFF regions relative to the X-axis are arranged in an alternating pattern relative to the Y-axis so that the portion of flow path 106D along each of each of first column C1 and second column C2 has a corresponding serpentine shape. More particularly, the serpentine shape of the portion of flow path 106D along each of first column C1 and second column C2 is a self-overlapping serpentine shape. Serpentine-configured flow path 106D of MBFF 102D has advantages over a counterpart sawtooth-configured flow path according to the other approach that are similar to the advantages that serpentine-configured flow path 106B of MBFF 102B has over the sawtooth-configured flow path of the counterpart thereto according to the other approach.

FIG. 1E is a block diagram of a semiconductor device 100E which includes an MBFF region 102E, in accordance with some embodiments.

MBFF 102E of FIG. 1E is similar to MBFF 102A of FIG. 1A. FIG. 2C (discussed below) is a layout diagram of an MBFF region corresponding to MBFF region 102E.

In FIG. 1E, the stacking order of SBFF regions in second column C2 is different than in FIG. 1A. Relative to the Y-axis, in second column C2, region SBFF7 is stacked on region SBFF8. Region SBFF6 is stacked on region SBFF7. Region SBFF5 is stacked on region SBFF6. As such, second column C2, bit b(7) is at the bottom of the stack and bit b(4) is at the top of the stack relative the Y-axis such that the bit sequence from bottom to top is b(7)→b(6)→b(5)→b(4).

Because of the different stacking order of SBFF regions in second column C2 in FIG. 1E, the X-orientations of the SBFF regions in each of rows R1-R4 are the same in FIG. 1E as in FIG. 1A. As such, each of regions SBFF1, SBFF3, SBFF6 and SBFF8 in FIG. 1E has the first X-orientation, and each of regions SBFF2, SBFF4, SBFF5 and SBFF7 in FIG. 1E has the second X-orientation. The portion of flow path 106E along each of each of first column C1 and second column C2 has a corresponding non-overlapping serpentine shape.

Flow path 106E of a data signal in MBFF 102E is comprised of path fragments FE1-FE15. In FIG. 1E, path fragment FE4 is in sub-column SC11, path fragments FE2 and FE6 are in sub-column SC13. Path fragment FE12 is in sub-column SC21. Path fragments FE10 and FE14 are in sub-column SC231.

Each of path fragments FE2, FE4 and FE6 extends upwardly from a first row into a first-adjacent second row. Path fragment FE2 extends upwardly from row R1 into row R2. Path fragment FE4 extends upwardly from row R2 to row R3. Path fragment FE6 extends upwardly from row R3 into row R4. Each of path fragments FE10, FE12 and FE14 extends downwardly from a first row into a first-adjacent second row. Path fragment FE10 extends downwardly from row R4 into row R3. Path fragment FE12 extends downwardly from row R3 into row R2. Path fragment FE14 extends downwardly from row R2 into row R1.

The stacking order of SBFF regions in FIG. 1E results in the portion of flow path 106E along each of each of first column C1 and second column C2 having a non-self-overlapping serpentine shape. Serpentine-configured flow path 106E of MBFF 102B has advantages over a counterpart sawtooth-configured flow path according to the other approach that are similar to the advantages that serpentine-configured flow path 106A of MBFF 102A has over the sawtooth-configured flow path of the counterpart thereto according to the other approach.

In FIG. 1E, by coupling output SQ4 of region SBFF4 to input SI5 of region SBFF5, path fragment FE8 couples first column C1 to second column C2. Path fragment FE8 stays within row R4. In some embodiments, fragment FE8 is described as a horizontal fragment because it couples the top of first column C1. i.e., output SQ4 of region SBFF4, to the top of second column C2, i.e., to input SI5 of region SBFF5. In some embodiments, the two-dimensional representation of an overall flow path of a data signal in MBFF 102E is described as resembling an uppercase letter Π, i.e., as being Π-shaped.

In FIG. 1E, each of rows R1-R4 has the first Y-orientation. In some embodiments, all (FIG. 1H) or some of the rows of MBFF region 102E have the second Y-orientation.

FIG. 1F is a block diagram of a semiconductor device 100F which includes an MBFF region 102E, in accordance with some embodiments.

MBFF 102F of FIG. 1F is similar to MBFF 102E of FIG. 1E. FIG. 2D (discussed below) is a layout diagram of an MBFF region corresponding to MBFF region 102F.

In FIG. 1F, the X-orientations of the SBFF regions in each of first column C1 and second column C2 are different than in FIG. 1E. In each row of FIG. 1F, the X-orientations of the SBFF regions are the same; by contrast, in each row of FIG. 1E, the X-orientations of the SBFF regions are different. Each of regions SBFF2, SBFF4, SBFF5 and SBFF7 in FIG. 1F has the first X-orientation. Each of regions SBFF1. SBFF3, SBFF6 and SBFF8 in FIG. 1F has the second X-orientation. The portion of flow path 106F along each of each of first column C1 and second column C2 has a corresponding non-overlapping serpentine shape.

Flow path 106F of a data signal in MBFF 102F is comprised of path fragments FF1-FF15. In FIG. 1F, path fragments FF2 and FF6 are in sub-column SC11. Path fragment FF4 is in sub-column SC13. Path fragment FF12 is in sub-column SC21. Path fragments FF10 and FF14 are in sub-column SC23.

The stacking order of SBFF regions in FIG. 1F results in the portion of flow path 106F along each of each of first column C1 and second column C2 having a non-self-overlapping serpentine shape. Serpentine-configured flow path 106F of MBFF 102B has advantages over a counterpart sawtooth-configured flow path according to the other approach that are similar to the advantages that serpentine-configured flow path 106A of MBFF 102F has over the sawtooth-configured flow path of the counterpart thereto according to the other approach.

In FIG. 1F, by coupling output SQ4 of region SBFF4 to input SI5 of region SBFF5, path fragment FF8 couples first column C1 to second column C2. Path fragment FF8 stays within row R4. In some embodiments, fragment FF8 is described as a horizontal fragment because it couples the top of first column C1, i.e., output SQ4 of region SBFF4, to the top of second column C2, i.e., to input SI5 of region SBFF5. In some embodiments, the two-dimensional representation of an overall flow path of a data signal in MBFF 102F is described as resembling an uppercase letter Π, i.e., as being Π-shaped.

In FIG. 1F, each of rows R1-R4 has the first Y-orientation. In some embodiments, all (FIG. 1H) or some of the rows of MBFF region 102F have the second Y-orientation.

FIG. 1G is a block diagram of a semiconductor device 100G which includes an MBFF region 102G, in accordance with some embodiments.

MBFF 102G of FIG. 1G is similar to MBFF 102A of FIG. 1A. FIG. 2B (discussed below) is a layout diagram of an MBFF region corresponding to MBFF region 102G.

In FIG. 1G, each of rows R2 and R4 has the second Y-orientation. By contrast, each of rows R2 and R4, as well as rows R1 and R3, in FIG. 1A has the first Y-orientation.

FIG. 1H is a block diagram of a semiconductor device 100H which includes an MBFF region 102H, in accordance with some embodiments.

MBFF 102H of FIG. 1H is similar to MBFF 102F of FIG. 1F. FIG. 2H (discussed below) is a layout diagram of an MBFF region corresponding to MBFF region 102H.

In FIG. 1H, each of rows R1-R4 has the second Y-orientation. In some embodiments, all (FIG. 1F) or some of the rows of MBFF region 102H have the first Y-orientation.

FIG. 1I is a block diagram of a semiconductor device 100I which includes an MBFF region 102I, in accordance with some embodiments.

MBFF 102I of FIG. 1I is similar to MBFF 102E of FIG. 1E.

The X-orientations of the SBFF regions in second column C2 are different than in FIG. 1E. In each row of FIG. 1I, the X-orientations of the SBFF regions are the same; by contrast, in each row of FIG. 1E, the X-orientations of the SBFF regions are different. As such, each of regions SBFF1, SBFF3, SBFF6 and SBFF8 in FIG. 1I has the first X-orientation, and each of regions SBFF2, SBFF4, SBFF5 and SBFF7 in FIG. 1I has the second X-orientation. The portion of flow path 106I along each of each of first column C1 and second column C2 has a corresponding non-overlapping serpentine shape.

Flow path 106I of a data signal in MBFF 102I is comprised of path fragments FI1-FI15. In FIG. 1I, path fragment FI4 is in sub-column SC11, path fragments FI2 and FI6 are in sub-column SC13. Path fragments FI10 and FI14 are in sub-column SC21. Path fragment FI12 is in sub-column SC23.

Each of path fragments FI2. FI4 and FI6 extends upwardly from a first row into a first-adjacent second row. Path fragment FI2 extends upwardly from row R1 into row R2. Path fragment FI4 extends upwardly from row R2 to row R3. Path fragment FI6 extends upwardly from row R3 into row R4. Each of path fragments FI10, FI12 and FI14 extends downwardly from a first row into a first-adjacent second row. Path fragment FI10 extends downwardly from row R4 into row R3. Path fragment FI12 extends downwardly from row R3 into row R2. Path fragment FI14 extends downwardly from row R2 into row R1.

The stacking order of SBFF regions in FIG. 1I results in the portion of flow path 106I along each of each of first column C1 and second column C2 having a non-self-overlapping serpentine shape. Serpentine-configured flow path 106I of MBFF 102B has advantages over a counterpart sawtooth-configured flow path according to the other approach that are similar to the advantages that serpentine-configured flow path 106A of MBFF 102A has over the sawtooth-configured flow path of the counterpart thereto according to the other approach.

In FIG. 1I, by coupling output SQ4 of region SBFF4 to input SI5 of region SBFF5, path fragment FI8 couples first column C1 to second column C2. Path fragment FI8 stays within row R4. In some embodiments, fragment FI8 is described as a horizontal fragment because it couples the top of first column C1, i.e., output SQ4 of region SBFF4, to the top of second column C2, i.e., to input SI5 of region SBFF5. In some embodiments, the two-dimensional representation of an overall flow path of a data signal in MBFF 102I is described as resembling an uppercase letter Π, i.e., as being Π-shaped.

In FIG. 1I, each of rows R1-R4 has the first Y-orientation. In some embodiments, all (FIG. 1H) or some of the rows of MBFF region 102I have the second Y-orientation.

FIG. 2A is a layout diagram of a multi-bit flip flop (MBFF) region 202A, in accordance with some embodiments.

MBFF region 202A of FIG. 2A corresponds to MBFF region 102A of FIG. 1A.

In general, a layout diagram represents a semiconductor device. Shapes in the layout diagram represent corresponding components in the semiconductor device. The layout diagram per se is a top view. Shapes in the layout diagram are two-dimensional relative to, e.g., the X-axis and the Y-axis, whereas the semiconductor device being represented is three-dimensional. Typically, relative to the Z-axis, the semiconductor device is organized as a stack of layers in which are located corresponding structures, i.e., to which belong corresponding structures. Accordingly, each shape in the layout diagram represents, more particularly, a component in a corresponding layer of the corresponding semiconductor device. Typically, the layout diagram represents relative depth, i.e., positions along the Z-axis, of shapes and thus layers by superimposing a second shape on a first shape so that the second shape at least partially overlaps the first shape. For simplicity of discussion, i.e., as a discussion-expedient, some elements in a layout diagram (e.g., FIGS. 2A-2C, or the like) are referred to as if they are counterpart structures in a corresponding semiconductor device rather than patterns/shapes per se.

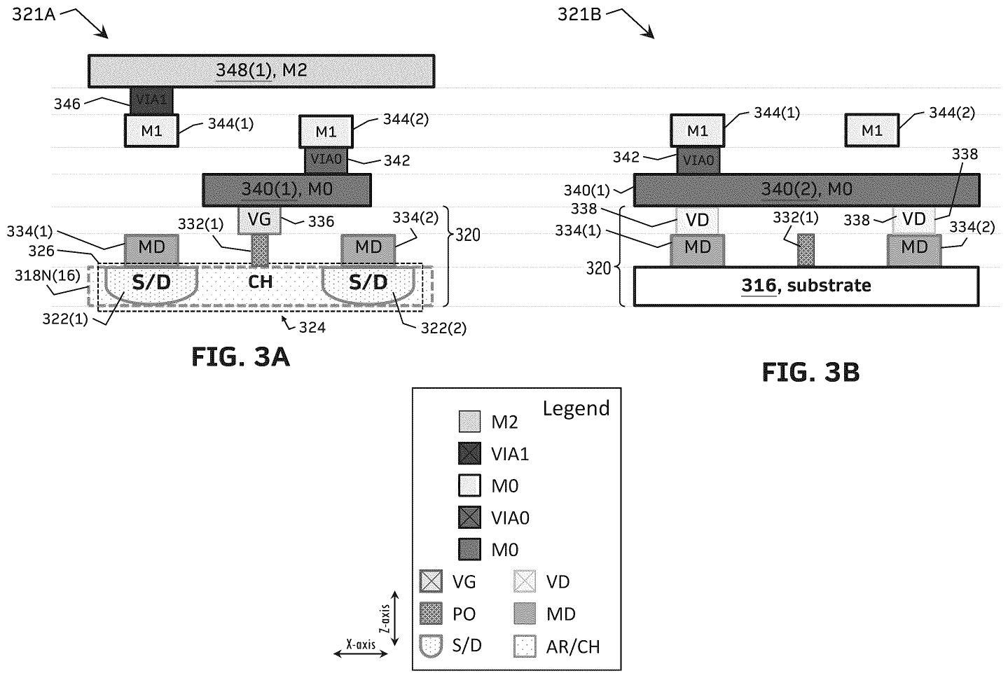

Layout diagrams vary in terms of the amount of detail represented. In some circumstances, selected layers of a layout diagram are combined/abstracted into a single layer, e.g., for purposes of simplification. Alternatively, and/or additionally, in some circumstances, not all layers of the corresponding semiconductor device are represented, i.e., selected layers of the layout diagram are omitted, e.g., for simplicity of illustration. FIGS. 2A-2E are examples of layout diagrams in which selected layers have been omitted. As a particular example, each of FIGS. 2A-2E omit layers (FIGS. 3A-3B) of the corresponding semiconductor device that are beneath the layer which includes via-to-M_1st (VIA0) contact structures (FIGS. 3A-3B). In some embodiments, the layout diagram of FIG. 2A is part of a larger layout diagram.

Like MBFF region 102A of FIG. 1A, MBFF region 202A of FIG. 2A includes SBFF regions SBFF1-SBFF8. For simplicity of illustration, however, the boundaries of only regions SBFF1 and SBFF8 are emphasized in FIG. 2A.

In FIG. 2A, each of the SBFF regions includes at least one first active region (AR) and at least one second AR. The first AR has a first type of conductivity and the second AR has a different second type of conductivity. For simplicity of illustration, FIG. 2A shows a single first AR and a single second AR in each of the SBFF regions. In some embodiments, the layout diagram of FIG. 2A is part of a larger layout diagram. The first ARs and the second ARs extend in a first direction (e.g., parallel to the X-axis).

In FIG. 2A, as in FIG. 1A, the following is assumed: the first type of conductivity is a positive-type (P-type) conductivity, as indicated by a label PMOS, where PMOS is an acronym for the phrase positive-channel metal-oxide-semiconductor (MOS) or the phrase P-channel MOS; and the second type of conductivity is a negative-type (N-type) of conductivity, as indicated by a label NMOS, where NMOS is an acronym for the phrase negative-channel metal-oxide-semiconductor (MOS) or the phrase N-channel MOS. In some embodiments, the first type of conductivity is a negative-type (N-type) of conductivity and that the second type of conductivity is a positive-type (P-type) conductivity.

MBFF 202A includes PMOS ARs 218P(1)-218P(4) and NMOS ARs 218N(1)-218N(4). ARs 218P(1) and 218N(1) are in row R1. ARs 218P(2) and 218N(2) are in row R2. ARs 218P(3) and 218N(3) are in row R3. ARs 218P(4) and 218N(4) are in row R4.

In FIG. 2A, as in FIG. 1A, each of rows R1-R4 has the first Y-orientation in which the first AR is stacked on the second AR relative to the Y-axis, i.e., a PMOS AR is stacked on an NMOS AR.

Relative to the X-axis, transistors (FIGS. 4A-4B) that comprise each of the regions SBFF1-SBFF8 of FIG. 2A are organized to include three areas (or portions): a first outside area (or portion) OP, a middle area (or portion) MID and a second outside area (or portion) OP2. For each of the SBFF regions, first outside area OP1 corresponds approximately to the input region of the SBFF region, and second outside areas OP2 corresponds approximately to the output region of the SBFF region.

Regarding each of FIGS. 1A-1H and 2A-2E, the following is to be recalled: first column C1 includes sub-columns SC11-SC13; second column C2 includes sub-columns SC21-SC23; the first X-orientation of each SBFF region is assumed to have the input region substantially in the first sub-column (SC11 or SC21) and the output region substantially in the third sub-column (SC13 or SC23); and the second X-orientation of each SBFF region is assumed to have the input region substantially in the third sub-column (SC13 or SC23) and the output region of the SBFF substantially in the first sub-column (SC11 or SC21).

In light of such recollection, the first X-orientation of the SBFF regions of FIG. 2A has first outside area OP1 and OP1 approximately in the first sub-column (SC11 or SC21) and second outside areas OP4 in the third sub-column (SC13 or SC23); and the second X-orientation of the SBFF regions of FIG. 2A has second outside area OP2 approximately in the third sub-column (SC13 or SC23) and the first outside area OP1 approximately in the first sub-column (SC11 or SC21).

Among the layers (FIGS. 3A-3B) of the corresponding semiconductor device which are omitted from FIG. 2A (and likewise FIGS. 2B-2E) is a first layer of metallization (M_1st layer). Segments in the M_1st layer (M_1st segments) extend parallel to the X-axis.

In some embodiments, depending upon the numbering convention of the corresponding process node by which a semiconductor device corresponding to the layout diagram of FIG. 2A is fabricated, M_1st layer is either metallization layer zero, M0, or metallization layer one, M1, and correspondingly the first layer of interconnection VIA_1st is either VIA0 or VIA1. In FIGS. 2A-2E, the M_1st layer is assumed to be M0 and the VIA_1st is assumed to be VIA0 In some embodiments, M0 is the first layer of metallization above a transistor layer (320 FIGS. 3A-3B, discussed below) in which transistors are formed.

In FIG. 2A, MBFF 202A further includes via-to-M0 (VIA0) contact structures 242, segments M1(1)-M1(8), via-to-M1 (VIA1) contact structures 246, and a segment M2(1).

VIA0 contact structures 242 are in a first layer of interconnection and are over corresponding segments (FIGS. 3A-3B) in the M_0 layer (M0 segments). Segments M1(1)-M1(8) are in a second layer of metallization (M_2nd layer, which is assumed to be the M1 layer in FIG. 2A)). Segments M1(1)-M1(8) extend in a second direction (e.g., parallel to the Y-axis) perpendicular to the first direction. In some embodiments, the first and second directions are something other than directions which are correspondingly parallel to the X-axis and the Y-axis. Portions of segments M1(1)-M1(8) are correspondingly over VI0A contact structures 242. For simplicity of illustration, VIA0 contact structures 242 appear in FIG. 2A to be correspondingly over segments M1(1)-M1(8); however, it is to be understood that VIA0 contact structures 242 are correspondingly under segments M1(1)-M1(8).

In MBFF 202A, VIA1 contact structures 246 are in a second layer of interconnection and are correspondingly over segments M1(7)-M1(8). Segment M2(1) is in a third layer of metallization (M_3rd layer, which is assumed to be the M2 layer in FIG. 2A)). Segment M2(1) extends parallel to the X-axis. For simplicity of illustration, VIA1 contact structures 246 appear in FIG. 2A to be correspondingly over segment M2(1); however, it is to be understood that VIA1 contact structures 246 are correspondingly under segment M2(1).

Segments M1(1)-M1(6) of FIG. 2A correspond to path segments FA2, FA4, FA6, FA10, FA12 and FA14 of flow path 106A of FIG. 1A. Segments M1(7), M2(1) and M1(8) of FIG. 2A together correspond to path segment FA8 in flow path 106A of FIG. 1A. As such, FIG. 2A has a flow path (not shown) corresponding to flow path 106A of FIG. 1A.

The portion of flow path of FIG. 2A along each of each of first column C1 and second column C2 has a corresponding non-overlapping serpentine shape. The serpentine-configured flow path of MBFF 202A has advantages over a counterpart sawtooth-configured flow path according to the other approach that are similar to the advantages that serpentine-configured flow path 106A of MBFF 102A has over the sawtooth-configured flow path of the counterpart thereto according to the other approach.

According to the other approach, a counterpart 8-bit MBFF region of a semiconductor device includes two counterpart columns represented by corresponding stacks of SBFF regions. The counterpart 8-bit MBFF region includes a counterpart third layer of metallization (M_3rd layer, which is assumed to be the M2 layer). According to the sawtooth-configured flow path of the other approach, in each of the second to eighth SBFF regions, one M2 segment is used to couple the input region of the SBFF region to the output region of the SBFF region. As a result, the MBFF region according to the other approach uses a total of (2*N)−2 of the M1 segments for inter-SBFF coupling, i.e., 14 of the M1 segments where N=8, which increases routing congestion in the M1 layer for the area above the counterpart MBFF region and thus diminishes routing opportunities in the M1 layer for the area above the counterpart MBFF region. Also as a result, the MBFF region according to the other approach uses a total of N−1 of the M2 segments for intra-SBFF coupling. i.e., 7 of the M2 segments where N=8, which increases routing congestion in the M2 layer for the area above the counterpart MBFF region thus diminishes routing opportunities M2 layer for the area above the counterpart MBFF region. By contrast, the serpentine-configured flow path of MBFF 202A uses N of the M1 segments, i.e., 8 of the M1 segments where N=8, for inter-SBFF coupling, which (as compared to the counterpart MBFF) reduces routing congestion in the M1 layer for the area above the counterpart MBFF region and thus increases routing opportunities in the M1 layer for the area above the counterpart MBFF region. Also by contrast, the serpentine-configured flow path of MBFF 202A uses one of the M2 segments for intra-SBFF coupling, which (as compared to the counterpart MBFF) reduces routing congestion in the M2 layer for the area above the counterpart MBFF region and thus increases routing opportunities in the M2 layer for the area above the counterpart MBFF region.

FIG. 2B is a layout diagram of a multi-bit flip flop (MBFF) region 202B, in accordance with some embodiments.

MBFF region 202B of FIG. 2B corresponds to MBFF region 102G of FIG. 1G. Recalling that MBFF region 102G is similar to MBFF region 102A, accordingly, MBFF region 202B of FIG. 2B is similar to MBFF region 202A of FIG. 2A.

MBFF 202B includes PMOS ARs 218P(5)-218P(8) and NMOS ARs 218N(5)-218N(8). ARs 218P(5) and 218N(5) are in row R1. ARs 218P(6) and 218N(6) are in row R2. ARs 218P(7) and 218N(7) are in row R3. ARs 218P(8) and 218N(8) are in row R4.

In FIG. 2B, each of rows R2 and R4 has the second Y-orientation. By contrast, each of rows R2 and R4, as well as rows R1 and R3, in FIG. 2A has the first Y-orientation.

FIG. 2C is a layout diagram of a multi-bit flip flop (MBFF) region 202C, in accordance with some embodiments.

MBFF region 2022C of FIG. 2C corresponds to MBFF region 102E of FIG. 1E. MBFF region 202C of FIG. 2C is similar to MBFF region 202A of FIG. 2A.

Like MBFF region 102E of FIG. 1E, MBFF region 202C of FIG. 2C includes SBFF regions SBFF1-SBFF8. For simplicity of illustration, however, the boundaries of only regions SBFF1 and SBFF5 are emphasized in FIG. 2C.

MBFF 202C of FIG. 2C differs from MBFF 202A of FIG. 2A. e.g., in terms of segments in layers M1 and M2. MBFF 202C does not include segments M1(7)-M1(8) and M2(1) of MBFF 202A, but instead includes segments M1(9)-M1(10) and M2(2). Segments M1(1)-M1(6) of FIG. 2C correspond to path segments FE2, FE4, FE6, FE10, FE12 and FE14 of flow path 106E of FIG. 1E. Segments M1(9)-M1(10) and M2(2) of FIG. 2C together correspond to path segment FE8 in flow path 106E of FIG. 1E. As such, FIG. 2C has a flow path (not shown) corresponding to flow path 106E of FIG. 1E.

The portion of flow path of FIG. 2C along each of each of first column C1 and second column C2 has a corresponding non-overlapping serpentine shape. The serpentine-configured flow path of MBFF 202C has advantages over a counterpart sawtooth-configured flow path according to the other approach that are similar to the advantages that serpentine-configured flow path 106E of MBFF 102E has over the sawtooth-configured flow path of the counterpart thereto according to the other approach.

In terms of reductions in the number of segments in the M1 layer used/consumed by the serpentine-configured flow path of MBFF 202C as compared to a counterpart MBFF according to the other approach, the serpentine-configured flow path of MBFF 202C reduces routing congestion in the M1 layer for the area above the counterpart MBFF region and thus increases routing opportunities in the M1 layer for the area above the counterpart MBFF region, similarly to how MBFF 202A of FIG. 2A reduces M1-routing congestion and increase M1-routing opportunities as compared to the MBFF according to the other approach which is a counterpart to MBFF 202A.

In terms of reductions in the number of segments in the M2 layer used/consumed by the serpentine-configured flow path of MBFF 202C as compared to a counterpart MBFF according to the other approach, the serpentine-configured flow path of MBFF 202C reduces routing congestion in the M2 layer for the area above the counterpart MBFF region and thus increases routing opportunities in the M2 layer for the area above the counterpart MBFF region, similarly to how MBFF 202A of FIG. 2A reduces M2-routing congestion and increase M2-routing opportunities as compared to the MBFF according to the other approach which is a counterpart to MBFF 202A.

FIG. 2D is a layout diagram of a multi-bit flip flop (MBFF) region 202D, in accordance with some embodiments.

MBFF region 202C of FIG. 2D corresponds to MBFF region 102F of FIG. 1F. MBFF region 202D of FIG. 2D is similar to MBFF region 202A of FIG. 2A.

Like MBFF region 102F of FIG. 1F, MBFF region 202D of FIG. 2D includes SBFF regions SBFF1-SBFF8. For simplicity of illustration, however, the boundaries of only regions SBFF1 and SBFF5 are emphasized in FIG. 2D.

In FIG. 2D, section line 3A-3A′ corresponds to cross-section 321A in FIG. 3A. Also in FIG. 2D, section line 3B-3B′ corresponds to cross-section 321B in FIG. 3B.

MBFF 202D includes PMOS ARs 218P(13)-218P(16) and NMOS ARs 218N(13)-218N(16). ARs 218P(13) and 218N(13) are in row R1. ARs 218P(14) and 218N(14) are in row R2. ARs 218P(15) and 218N(15) are in row R3. ARs 218P(16) and 218N(16) are in row R4.

MBFF 202D of FIG. 2D differs from MBFF 202A of FIG. 2A, e.g., in terms of segments in layers M1 and M2. MBFF 202D does not include segments M1(1)-M1(8) and M2(1) of MBFF 202A, but instead includes segments M1(11)-M1(18) and M2(3). Segments M1(11)-M1(16) correspond to path segments FF2, FF4, FF6, FF10, FF12 and FF14 in flow path 106F of FIG. 1E. Segments M1(17)-M1(18) and M2(3) of FIG. 2D together correspond to path segment FF8 in flow path 106E of FIG. 1F. As such, FIG. 2D has a flow path (not shown) corresponding to flow path 106E of FIG. 1F.

The portion of flow path of FIG. 2D along each of each of first column C1 and second column C2 has a corresponding non-overlapping serpentine shape. The serpentine-configured flow path of MBFF 202D has advantages over a counterpart sawtooth-configured flow path according to the other approach that are similar to the advantages that serpentine-configured flow path 106E of MBFF 102F has over the sawtooth-configured flow path of the counterpart thereto according to the other approach.

In terms of reductions in the number of segments in the M1 layer used/consumed by the serpentine-configured flow path of MBFF 202D as compared to a counterpart MBFF according to the other approach, the serpentine-configured flow path of MBFF 202D reduces routing congestion in the M1 layer for the area above the counterpart MBFF region and thus increases routing opportunities in the M1 layer for the area above the counterpart MBFF region, similarly to how MBFF 202A of FIG. 2A reduces M1-routing congestion and increase M1-routing opportunities as compared to the MBFF according to the other approach which is a counterpart to MBFF 202A.

In terms of reductions in the number of segments in the M2 layer used/consumed by the serpentine-configured flow path of MBFF 202D as compared to a counterpart MBFF according to the other approach, the serpentine-configured flow path of MBFF 202D reduces routing congestion in the M2 layer for the area above the counterpart MBFF region and thus increases routing opportunities in the M2 layer for the area above the counterpart MBFF region, similarly to how MBFF 202A of FIG. 2A reduces M2-routing congestion and increase M2-routing opportunities as compared to the MBFF according to the other approach which is a counterpart to MBFF 202A.

FIG. 2E is a layout diagram of a multi-bit flip flop (MBFF) region 202E, in accordance with some embodiments.

MBFF region 202E of FIG. 2E corresponds to MBFF region 102H of FIG. 1H. Recalling that MBFF region 102H is similar to MBFF region 102F, accordingly, MBFF region 202E of FIG. 2E is similar to MBFF region 202D of FIG. 2D.

In FIG. 2E, each of rows R1-R4 has the second Y-orientation. By contrast, each of rows R1-R4 FIG. 2D has the first Y-orientation.

FIGS. 3A-3B are corresponding cross-sections 321A and 321 of an MBFF region in a semiconductor device based on the layout diagram of MBFF region 202D of FIG. 2D, in accordance with some embodiments.

Regarding FIG. 3A, cross-section 321A corresponds to section line 3A-3A′ in FIG. 2D. Regarding FIG. 3B, cross-section 321B corresponds to section line 3B-3B′ in FIG. 2D.

In FIG. 3A, AR 318N(16) includes source/drain (S/D) regions 322(1) and 322(2). Relative to an initial (first) concentration of negative-type (N-type) dopant(s) otherwise present in non-S/D areas of AR 318N(16), each of S/D regions 322(1) and 322(2) has a second concentration of negative-type (N-type) dopant(s) which is different than the first concentration. AR 318N(16) is formed in a substrate 316. Together, source/drain (S/D) regions 322(1) and 322(2), an area 324 between S/D regions 322(1) and 322(2), plus a gate segment 332(1) comprise a transistor 326, where area 324 represents an invertible region commonly referred to as a channel region. In some embodiments, transistor 326 is an N-type field-effect transistor (N-type FET). In some embodiments, transistor 326 more specifically is an N-type metal-oxide-semiconductor FET (N-type MOSFET). In some embodiments, transistor 326 is a type of transistor other than an N-type FET. A different cross-section (not shown) of FIG. 2D that crosses one of P-type ARs 218P(13)-218P(16) would show third and fourth S/D regions of a third concentration of positive-type (P-type) dopant(s) which is different than an initial (fourth) concentration of P-type dopant(s) otherwise present in non-S/D areas of the P-type AR, with a P-type channel between the third and fourth P-type S/D regions, plus a gate segment over the P-channel region, which together comprise a P-type MOSFET.

Regarding FIG. 3B, no AR is present. Accordingly, relative to a third direction (e.g., Z-axis) perpendicular to each of the first direction (e.g., X-axis) and the second direction (e.g., Y-axis), the layer occupied by AR 318N(16) in FIG. 3A is shown as substrate 316 in FIG. 3B.

FIGS. 3A-3B further include a gate segment 332(1) and metal-to-S/D (MD) contact structures 334(1) and 334(2) which extend parallel to the Y-axis. In FIG. 3A, gate segment 332(1) is aligned over channel region 324, and MD contact structures 334(1)-334(2) are correspondingly aligned over S/D regions 322(1)-322(2), relative to the X-axis.

FIG. 3A further includes a via-to-gate (VG) contact structure 336 over gate segment 332(1). FIG. 3B further includes via-to-MD (VD) contact structures correspondingly over MD contact structures 334(1)-334(2). MD contact structures 334(1)-334(2) extend parallel to the Y-axis. Together, the layers which correspondingly include AR 318N(16), gate segment 332(1), MD contact structures 334(1)-334(2), VG contact structure 336 and VG contact structures 338 represent a transistor layer 320.

FIGS. 3A-3B further include corresponding segments 340(1) and 340(2) in a first metallization (M_1st) layer (M_1st segment) which are electrically conductive, where the M_1st layer is assumed to be the M0 layer for consistency with FIG. 2D. M_1st segments 340(1)-340(2) extend parallel to the X-axis. M_1st segment 340(1) in FIG. 3A is over VG 336. M_1st segment 340(2) in FIG. 3B is over instances of VD 338.

FIGS. 3A-3B further include via-to-M0 (VIA0) contact structures 342 correspondingly aligned over M_1st segments 340(1)-340(2).

FIGS. 3A-3B further include segments 344(1) and 344(2) in a second metallization (M_2nd) layer (M_2nd segment) which are electrically conductive, where the M_2nd layer is assumed to be the M1 layer for consistency with FIG. 2D. M_2nd segments 344(1)-344(2) extend parallel to the Y-axis. M_2nd segment 344(2) in FIG. 3A is over an instance of VIA0 342. M_2nd segment 344(2) in FIG. 3B is over another instance of VIA0 342.

FIGS. 3A-3B further include via-to-M1 (VIA1) contact structure 346 correspondingly aligned over M_1st segment 344(1).

FIG. 3A further includes a segment 348(1) in a third metallization (M_3rd) layer (M_3rd segment) which are electrically conductive, where the M_3rd layer is assumed to be the M2 layer for consistency with FIG. 2D. M_3rd segment 348(1) extends parallel to the X-axis. M_3rd segment 348(2) in FIG. 3A is over VIA1 346.

FIGS. 4A-4B are corresponding schematic circuit diagrams, in accordance with some embodiments.

More particularly, FIGS. 4A-4B are corresponding schematic circuit diagrams of scan D FF (SDFQs) 430A and 430B. Each of SDFQ 430A of FIG. 4A and SDFQ 430B of FIG. 4B is an example of the SBFF regions in each of FIGS. 1A-1H and 2A-2E.

FIG. 4A differs from FIG. 4B in that SDFQ 430A is a transmission-gate-based design (discussed below) whereas SDFQ 430B is a stack-gate-based design (discussed below). Each of SDFQ 430A and SDFQ 430B is an edge-triggered arrangement that is triggered on a rising edge (positive edge) of a clock signal. Variations to make each of SDFQ 430A and SDFQ 430B be triggered on the falling edge (negative edge) of the clock signal are discussed below.

Relative to the X-axis, transistors that comprise each of SDFQ 430A of FIG. 4A and SDFQ 430B of FIG. 4B are organized to include three areas (or portions). SDFQ 430A of FIG. 4A includes a first outside area (or portion) OP41A, a middle area (or portion) MID4A and a second outside area (or portion) OP4A2. SDFQ 430B of FIG. 4B includes a first outside area (or portion) OP4B1, a middle area (or portion) MID4B and a second outside area (or portion) OP4B2. First outside areas OP4A1 and OP4B1 correspond approximately to the input region of each SBFF region in each of FIGS. 1A-1H and 2A-2E. Second outside areas OP4A2 and OP4B2 correspond approximately to the output region of each SBFF region in each of FIGS. 1A-1H and 2A-2E.

Regarding each of FIGS. 1A-1H and 2A-2E, the following is to be recalled: first column C1 includes sub-columns SC11-SC13; second column C2 includes sub-columns SC21-SC23; the first X-orientation of each SBFF region is assumed to have the input region substantially in the first sub-column (SC11 or SC21) and the output region substantially in the third sub-column (SC13 or SC23); and the second X-orientation of each SBFF region is assumed to have the input region substantially in the third sub-column (SC13 or SC23) and the output region of the SBFF substantially in the first sub-column (SC11 or SC21).

In light of such recollection, in some embodiments, the first X-orientation of each of SDFQs 430A and 430B has corresponding first outside areas OP4A1 and OP4B1 approximately in the first sub-column (SC11 or SC21) and corresponding second outside areas OP4A2 and OP4B2 approximately in the third sub-column (SC13 or SC23); and the second X-orientation of each of SDFQs 430A and 430B has corresponding second outside areas OP4A2 and OP4B2 approximately in the third sub-column (SC13 or SC23) and corresponding first outside areas OP4A1 and OP4B1 approximately in the first sub-column (SC11 or SC21). Additional discussion of first outside areas OP4A1 and OP4B1, middle areas MID4A and MID4B, and second outside areas OP4A2 and OP4B2 is provided below.

In FIG. 4A, SDFQ 430A includes a multiplexer 432, a D flip-flop 434A, a scan buffer 444 and a clock buffer 446. SDFQ 430A further includes two types of inverter, namely a sleepy inverter and a non-sleepy (NS) inverter; the terms sleepy and non-sleepy are explained below.

In FIG. 4A, scan buffer 444 receives a Scan/Test Enable (SE)_signal that selects between normal operation relative to input signal D or a scan operation relative to a Scan-In (SI) signal. Scan buffer 444 includes a non-sleepy (NS) inverter 484(4), the latter including series-connected PFET P41 and NFET N41. An NS inverter, e.g., 448(4) is a counterpart to a sleepy inverter, e.g., 450(1) (discussed below). Hereinafter, transistors whose reference alphanumeric is prefixed with the uppercase letter P. e.g., P41, are PFETs, and transistors whose reference alphanumeric is prefixed with the uppercase letter N, e.g., N41, are NFETs.

In NS inverter 448(4), transistor P41 is connected between a node having a first reference voltage, e.g., VDD, and a node nd41. Transistor N41 is connected between node nd41 and a node having a second reference voltage, e.g., VSS. The gate terminals of each of transistors P41 and N41 are connected together and are configured to receive signal SE. Node nd41 has a signal seb which is the inversion of signal SE.

In FIG. 4A, clock buffer 446 includes a pair of NS inverters 448(5) and 448(6). NS inverter 448(5) includes series-connected transistors P31 and N31. Transistor P31 is connected between a node having voltage VDD and a node nd31. Transistor N31 is connected between node nd31 and a node having voltage VSS. The gate terminals of each of transistors P31 and N31 are connected together and are configured to receive a clock signal CP. Node nd31 represents an output node of NS inverter 448(5) and has a clock signal clkb which represents the inversion of clock signal CP.

In clock buffer 446, NS inverter 448(6) includes series-connected transistors P32 and N32. Transistor P32 is connected between a node having voltage VDD and a node nd32. Transistor N32 is connected between node nd32 and a node having voltage VSS. The gate terminals of each of transistors P32 and N32 are connected together and to node nd31, and thus are configured to receive clock signal clkb. Node nd32 represents an output node of NS inverter 448(6) and has a clock signal clkbb which represents the inversion of clock signal clkb.

In FIG. 4A, multiplexer 432 includes transistors P11-P15 and N11-N15. Transistor P11 is connected between a node having voltage VDD and a node nd11. The gate terminal of transistor P11 receives signal SI. Transistor P12 is connected between node nd11 and a node nd13. The gate terminal of transistor P12 receives signal seb. Transistor P13 is connected between a node having voltage VDD and a node nd12. The gate terminal of transistor P13 receives input signal D. Transistor P14 is connected between node nd12 and node nd13. The gate terminal of transistor P14 receives signal SE. Transistor P15 is connected between node nd13 and a node nd14 which has signal ml_ax. The gate terminal of transistor P15 receives signal clkbb. Transistor N11 is connected between node nd14 and a node nd15. The gate terminal of transistor N11 receives signal clkb. Transistor N12 is connected between node nd15 and a node nd16. The gate terminal of transistor N12 receives signal SE. Transistor N13 is connected between node nd16 and a node having voltage VSS. The gate terminal of transistor N13 receives signal SI. Transistor N14 is connected between node nd15 and a node nd17. The gate terminal of transistor N14 receives signal seb. Transistor N15 is connected between node nd17 and a node having voltage VSS. The gate terminal of transistor N15 receives input signal D.

In FIG. 4A, D flip-flop 434A includes a primary latch 436, an internal buffer 441A, a secondary latch 438 and an output buffer 442.

Primary latch 436 includes an NS inverter 448(1) and a sleepy inverter 450(1). NS inverter 448(1) includes transistors P21 and N21. Transistor P21 is connected between a node having voltage VDD and a node nd21. Transistor N21 is located node nd21 and a node having voltage VSS. The gate terminals of transistors P21 and N21 are connected together and to node nd14, and thus are configured to receive signal ml_ax. As such, signal ml_ax represents the input signal of D flip-flop 434A. Node nd21 represents an output node of NS inverter 448(1) and has a signal ml_b which represents the inversion of signal ml_ax.

In primary latch 436, sleepy inverter 450(1) includes transistors P22-P23 and N22-N23. Transistor P22 is connected between a node having voltage VDD and a node nd22. Transistor P23 is connected between node nd22 and node nd14. The gate terminal of transistor P23 receives signal clkb. Transistor N22 is connected between node nd14 and a node nd23. The gate terminal of transistor N22 receives signal clkbb. In some embodiments, the gate terminal of transistor N22 receives signal CP instead of signal clkbb. Transistor N23 is connected between node nd23 and a node having voltage VSS. Sleepy inverter 450(1) can be put into a sleep mode of operation due to transistors P23 and N22. By contrast, NS inverter 248(1) lacks transistors corresponding to transistors P23 and N22 such that inverter 248(1) of primary latch 236 lacks a sleep mode of operation; accordingly, NS inverter 248(1) is described as a non-sleepy (NS) inverter. The gate terminals of transistors P22 and N23 are connected together and to node nd21. Accordingly, sleepy inverter 450(1) feeds-back an inverted version of signal ml_b (from node nd21) to node nd14.

In FIG. 4A, internal buffer 441A includes a transmission gate 440, the latter including transistors P24 and N24. The inclusion of transmission 440 is SDFQ 430A is referred to as a transmission-gate-based design. Transistors P24 and N24 are connected in parallel between node nd21 and a node nd24. The gate of transistor P24 receives signal clkb. The gate terminal of transistor N24 receives signal clkbb. Node nd24 has a signal sl_a.

In D flip-flop 434A, secondary latch 438 includes an NS inverter 448(2) and a sleepy inverter 450(2). NS inverter 448(2) includes transistors P25 and N25. Transistor P25 is connected between a node having voltage VDD and a node nd25. Transistor N25 is connected between node nd25 and a node having voltage VSS. The gate terminals of transistors P25 and N25 are connected together and to node nd24, and thus are configured to receive signal sl_a. Node nd25 represents an output node of NS inverter 448(2) and has a signal sl_bx which represents the inversion of signal sl_a.

In secondary latch 438, sleepy inverter 450(2) includes transistors P26-P27 and N26-N27. Transistor P26 is connected between a node having voltage VDD and a node nd26. Transistor P27 is connected between node nd26 and node nd24. The gate terminal of transistor P27 receives signal clkbb. Transistor N26 is connected between node nd24 and a node nd27. Transistor N27 is connected between node nd27 and a node having voltage VSS. The gate terminal of transistor N26 receives signal clkb. Sleepy inverter 450(2) can be put into a sleep mode due to transistors P27 and N26. The gate terminals of transistors P22 and N23 are connected together and to node nd25. Accordingly, sleepy inverter 450(2) feeds-back an inverted version of signal sl_bx (from node nd25) to node nd24.

In D flip-flop 434A, output buffer 442 includes an NS inverter 448(3), the latter including transistors P28 and N28. Transistor P28 is connected between a node having voltage VDD and a node nd26. Transistor N28 is connected between node nd28 and a node having voltage VSS. The gate terminals of transistors P28 and N28 are connected together and to node nd25, and thus are configured to receive signal sl_bx. Node nd26 represents an output node of NS inverter 448(3), and thus of D flip-flop 434A. Furthermore, node nd26 also represents the output node of SDFQ 400. Node 464 has a signal SQ which represents the inversion of signal sl_bx.

It is to be recalled that SDFQ 430A is triggered on the rising edge (positive edge) of a clock signal. Variations to make SDFQ 430A be triggered on the falling edge (negative edge) of the clock signal include the following. Instead of receiving clock signal CP, the gate terminals of each of transistors P31 and N31 are configured to receive a clock signal CPN, where CPN is an inverted version of clock signal CP. Instead of receiving signal clkbb, the gate terminal of transistor P15 receives signal clkb. Instead of receiving signal clkb, the gate terminal of transistor N11 receives signal clkbb. Instead of receiving signal clkb, the gate terminal of transistor P23 receives signal clkbb. In some embodiments, the gate terminal of transistor P23 receives signal CPN instead of signal clkbb. Instead of receiving signal clkbb, the gate terminal of transistor N22 receives signal clkb. Instead of receiving signal clkb, the gate terminal of transistor P24 receives signal clkbb. Instead of receiving signal clkbb, the gate terminal of transistor N24 receives signal clkb. Instead of receiving signal clkbb, the gate terminal of transistor P27 receives signal clkb. Instead of receiving signal clkb, the gate terminal of transistor N26 receives signal clkbb.

In FIG. 4A, first side area OP4A1 includes scan buffer 444, multiplexer 432 and clock buffer 446. Middle portion MID4A includes some of the components of D flip-flop 434A. i.e., includes primary latch 436 and internal buffer 441A of D flip-flop 434A. Second outside portion OP4A2 includes remaining components of D flip-flop 434A, i.e., includes secondary latch 438 and output buffer 442 of D flip-flop 434A.

Regarding FIG. 4B, it is to be recalled that SDFQ 430B is a stack-gate-based design, whereas SDFQ 430A of FIG. 4A is a transmission-gate-based design. More particularly, whereas D flip-flop 434A of SDFQ 430A of FIG. 4A includes internal buffer 441A which includes transmission gate 440, D flip-flop 434B of SDFQ 430B of FIG. 4B includes internal buffer 441B. Internal buffer 4411B includes a sleepy inverter 450(3), the latter being an example of a stack-gate-based circuit.

In FIG. 4B, sleepy inverter 450(3) of internal buffer 441B includes transistors P51-P52 and N51-N52. Transistor P51 is connected between a node having voltage VDD and a node nd51. Transistor P52 is connected between node nd51 and node nd24. The gate terminal of transistor P52 receives signal clkb. Transistor N51 is connected between node nd24 and a node nd52. The gate terminal of transistor N51 receives signal clkbb. In some embodiments, the gate terminal of transistor N51 receives signal CP instead of signal clkbb. Transistor N52 is connected between node nd52 and a node having voltage VSS. The gate terminal of transistor N51 receives signal clkbb. Sleepy inverter 450(3) can be put into a sleep mode due to transistors P52 and N51. The gate terminals of transistors P51 and N52 are connected together and to node nd14. Accordingly, signal ml_ax is provided as the input to sleepy inverter 450(3). Unlike transmission gate 440 of FIG. 4A whose input receives signal ml_b from node nd21, the input of sleepy inverter 450(3) is not connected to node nd21. Rather, in FIG. 4B, only the input of sleepy inverter 450(1), i.e., the gate terminals of each of transistors P22 and N23, receive signal ml_b from node nd21.

It is to be recalled that SDFQ 430B is triggered on the rising edge (positive edge) of a clock signal. Variations to make SDFQ 430B be triggered on the falling edge (negative edge) of the clock signal include the following. Instead of receiving clock signal CP, the gate terminals of each of transistors P31 and N31 are configured to receive a clock signal CPN, where CPN is an inverted version of clock signal CP. Instead of receiving signal clkbb, the gate terminal of transistor P15 receives signal clkb. Instead of receiving signal clkb, the gate terminal of transistor N11 receives signal clkbb. Instead of receiving signal clkb, the gate terminal of transistor P23 receives signal clkbb. In some embodiments, the gate terminal of transistor P23 receives signal CPN instead of signal clkbb. Instead of receiving signal clkbb, the gate terminal of transistor N22 receives signal clkb. Instead of receiving signal clkb, the gate terminal of transistor P52 receives signal clkbb. Instead of receiving signal clkbb, the gate terminal of transistor N51 receives signal clkb. Instead of receiving signal clkbb, the gate terminal of transistor P27 receives signal clkb. Instead of receiving signal clkb, the gate terminal of transistor N26 receives signal clkbb.

In FIG. 4B, first side area OP4B1 includes scan buffer 444, multiplexer 432 and clock buffer 446. Middle portion MID4B includes some of the components of D flip-flop 434B, i.e., includes primary latch 436 and internal buffer 441B of D flip-flop 434B. Second outside portion OP4B2 includes remaining components of D flip-flop 434B, i.e., includes secondary latch 438 and output buffer 442 of D flip-flop 434B.

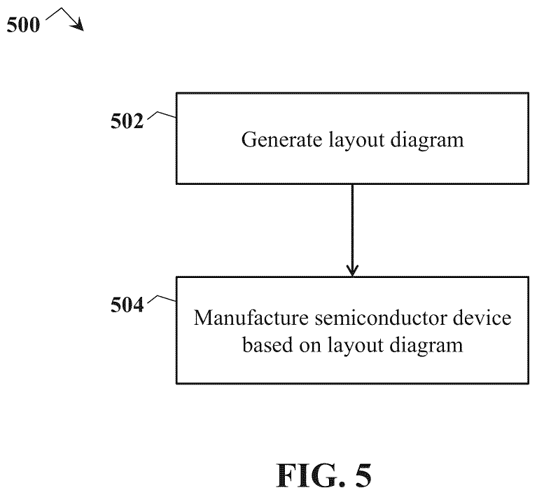

FIG. 5 is a flow diagram 500 of a method of manufacturing a semiconductor device, in accordance with some embodiments.

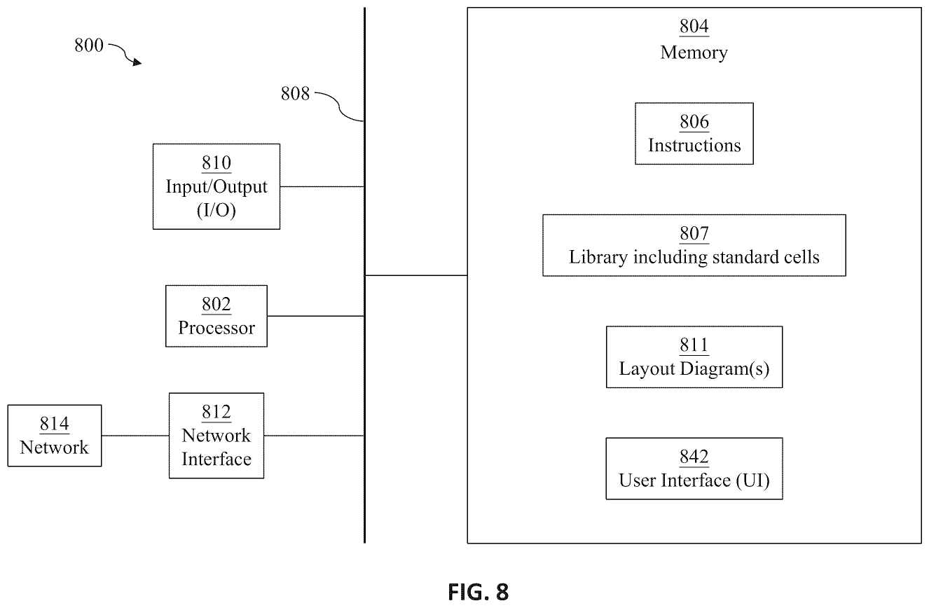

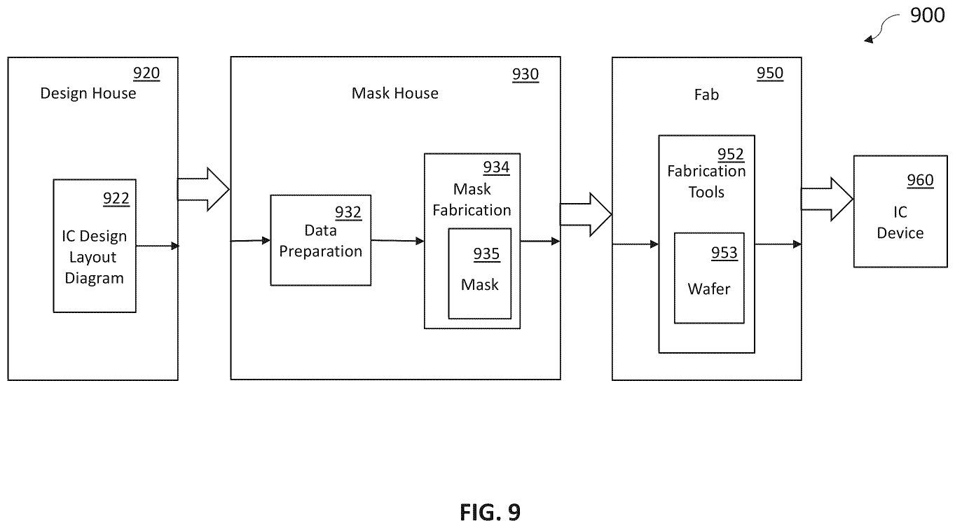

The method of flowchart (flow diagram) 500 is implementable, for example, using EDA system 800 (FIG. 8, discussed below) and an IC manufacturing system 900 (FIG. 9, discussed below), in accordance with some embodiments. Examples of a semiconductor device which can be manufactured according to the method of flowchart 500 include the semiconductor devices of FIGS. 1A-1H, semiconductor devices based on the layout diagrams disclosed herein, semiconductor devices based on the cross-sections disclosed herein, or the like.

In FIG. 5, the method of flowchart 500 includes blocks 502-504. At block 502, a layout diagram is generated which, among other things, includes one or more of layout diagrams disclosed herein, or the like. Block 502 is implementable, for example, using EDA system 800 (FIG. 8, discussed below), in accordance with some embodiments. From block 502, flow proceeds to block 504.

At block 504, based on the layout diagram, at least one of (A) one or more photolithographic exposures are made or (b) one or more semiconductor masks are fabricated or (C) one or more components in a layer of a semiconductor device are fabricated. See discussion below of IC manufacturing system 900 in FIG. 9 below.

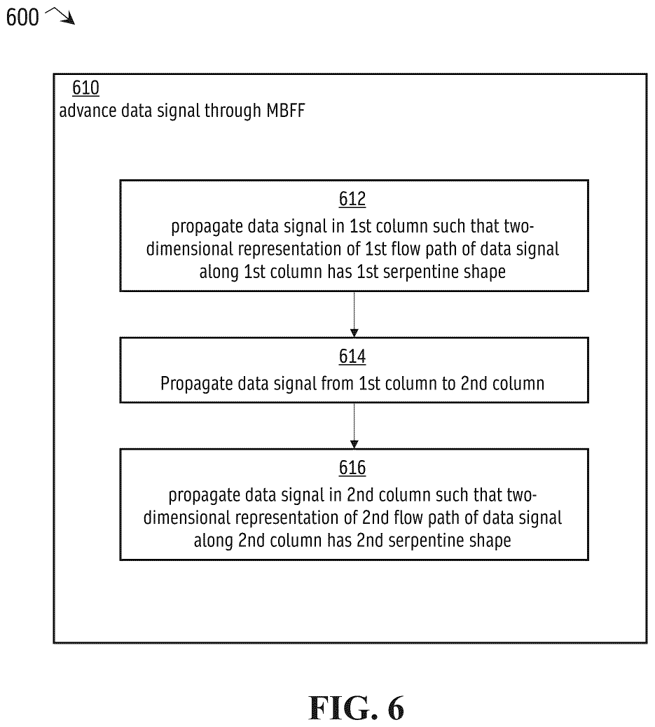

FIG. 6 is a flowchart 600 of a method of operating a multi-bit flip-flop (MBFF) region of a semiconductor device, in accordance with some embodiments.

Flowchart 600 includes a block 610, where block 610 includes blocks 612-616.

Examples of MBFF regions whose operation is illustrated by flowchart 600 include MBFF regions corresponding to the block diagrams of FIGS. 1A-1I, MBFF regions corresponding to the layout diagrams of FIGS. 2A-2E, or the like.

An MBFF region operated according to flowchart 600 is comprised of first to (N)th single-bit flip-flops (SBFF regions) regions correspondingly representing bits b0 to b(N−1) such that the MBFF is an N-bit MBFF, where N is a positive integer. The first to (N)th SBFF regions (e.g., SBFF1-SBFF8 of FIGS. 1A-1B, 1E-1I, 2A-2E, SBFF1-SBFF12 of FIGS. 1C-1D, or the like) are daisy-chain coupled in a numerically increasing sequence from the first SBFF region to the (N)th SBFF region. The input of the first SBFF region represents the input of the MBFF region. The output of the (N)th SBFF region represents the output of the MBFF region. The MBFF region has a two-dimensional floor plan represented by a grid including rows (e.g., rows R1-R4 of FIGS. 1A-1B, 1E-1I, 2A-2E, rows R1-R6 of FIGS. 1C-1D, or the like) and first (C1) and second (C2) columns extending in corresponding first (e.g., parallel to the X-axis) and perpendicular second (e.g., parallel to the Y-axis) directions, each SBFF region representing an intersection of a corresponding row and column.

Regarding the MBFF region operated according to flowchart 600, the first column (e.g., C1 of FIGS. 1A-11, 2A-2E, or the like) includes the first one of the SBFF regions to an (i+1)th one of the SBFF regions that correspondingly represent bits b(0) to b(i), where i is a positive integer and i<N. The second column (e.g. C2 of FIGS. 1A-11, 2A-2E, or the like) includes an (i+2)th one of the SBFF regions to the (N)th SBFF region that correspondingly represent bits b(i+1) to b(N−1).

In FIG. 6, at block 610, a data signal is advanced through the MBFF region. Examples of two-dimensional representations of a data signal being advanced through the MBFF regions are flow paths 106A-106I of FIGS. 1A-1I, the flow paths of FIGS. 2A-2E, or the like. Within block 610, flow proceeds to block 612.

At block 612, the data signal is propagated in the first column such that a two-dimensional representation of a first flow path of the data signal along the first column has a first serpentine shape. Examples of a first flow path along the first column which has a first serpentine shape include the portions of flow paths 106A-106I in column C1 of FIGS. 1A-1I, the portions of the flow paths of FIGS. 2A-2E which are in column C1, or the like. In some embodiments, the propagating the data signal in the first column propagates the data signal such the two-dimensional representation of the first flow path has a non-self-overlapping serpentine shape. In some embodiments, the propagating the data signal in the first column propagates the data signal such the two-dimensional representation of the first flow path has a self-overlapping serpentine shape. From block 612, flow proceeds to block 614.

At block 614, the data signal is propagated from the first column to the second column. Examples of propagating the data signal is propagated from the first column to the second column include flow path segment FA8 of FIG. 1A, flow path segment FB8 of FIG. 1B, flow path segment FC12 of FIG. 1C, flow path segment FDC12 of FIG. 1D, flow path segment FE8 of FIG. 1E, flow path segment FF8 of FIG. 1F, flow path segment FG8 of FIG. 1G, flow path segment FH8 of FIG. 1H, flow path segment FI8 of FIG. 1I, the flow path segment corresponding to segments M1(7)M1(-8) and M2(1) in FIGS. 2A-2B, the flow path segment corresponding to segments M1(9)-M1(10) and M2(2) in FIG. 2C, the flow path segment corresponding to segments M1(9)-M1(10) and M2(2) in FIG. 2C, the flow path segment corresponding to segments M1(17)-M1(18) and M2(3) in FIGS. 2D-2E, or the like. From block 614, flow proceeds to block 616.

At block 616, the data signal is propagated in the second column (C2) such that a two-dimensional representation of a second flow path of the data signal along the second column (C2) has a second serpentine shape. Examples of a second flow path along the second column which has a second serpentine shape include the portions of flow paths 106A-106I in column C2 of FIGS. 1A-1I, the portions of the flow paths of FIGS. 2A-2E which are in column C2, or the like. In some embodiments, the propagating the data signal in the second column propagates the data signal such the two-dimensional representation of the second flow path has a non-self-overlapping serpentine shape. In some embodiments, the propagating the data signal in the second column propagates the data signal such the two-dimensional representation of the second flow path has a self-overlapping serpentine shape.

In some embodiments regarding the MBFF region operated according to flowchart 600, each SBFF region has an input region at a first side of the SBFF region and an output region at an opposite second side of the SBFF region relative to the first direction (e.g., X-axis), each of the first (e.g., C1) and second (e.g., C2) columns includes at least first (e.g., SC11, SC21) and second (e.g., SC13, SC23) sub-columns. A first orientation for a given one of the SBFF regions relative to the X-axis (α-orientation) has the input region in the first sub-column (e.g., SC13, SC23) and the output region in the second sub-column (e.g., SC13, SC23). A second α-orientation for a given one of the SBFF regions has the input region in the second sub-column (e.g., SC13, SC23) and the output region in the first sub-column (e.g., SC11, SC21). For each of the first (e.g., C1) and second (e.g., C2) columns, the rows exhibit an alternating pattern of α-orientations such that the rows alternate between the first and second α-orientations. In such embodiments, regarding block 612, propagating the data signal in the first column (e.g., C1) includes communicating the data signal such that each portion of the two-dimensional representation of the first flow path which couples a preceding one of the first to (i+1)th SBFF regions to a succeeding one of the first to (i+1)th SBFF regions is parallel to the second direction (e.g., Y-axis); e.g., see FIGS. 1A-11, 2A-2E, or the like. In such embodiments, regarding block 616, propagating the data signal in the second column (e.g., C2) includes communicating the data signal such that each portion of the two-dimensional representation of the second flow path which couples a preceding one of the (i+2)th to (N)th SBFF regions to a succeeding one of the (i+2)th to (N)th SBFF regions is parallel to the second direction (e.g., Y-axis); e.g., see FIGS. 1A-11, 2A-2E, or the like.

In some embodiments regarding block 614, the propagating the data signal from the first column (e.g., C1) to the second column (e.g., C2) includes communicating the data signal such that a two-dimensional representation of a third flow path of the data signal from the first column (e.g., C1) to the second column (e.g., C2) includes a first portion that is parallel to the first direction (e.g., X-axis); e.g., see FIGS. 1A-11, 2A-2E, or the like.

In some embodiments regarding block 614, the communicating the data signal communicates a same such that the first portion of the third flow path extends from the first sub-column (e.g., SC11) of the first column (e.g., C1) to the second sub-column (e.g., SC23) of the second column (e.g., C2); e.g., see FIGS. 1A-1D, 1G, 1I, 2A-2B, 11, 2A-2E, or the like.

In some embodiments regarding block 614, the communicating the data signal communicates a same such that the first portion of the third flow path extends from the first sub-column (e.g., SC11) of the first column (e.g., C1) to the first sub-column (e.g., SC21) of the second column (e.g., C2); e.g., see FIGS. 1E, 2C, or the like.

In some embodiments regarding block 614, the communicating the data signal communicates a same such that the first portion of the third flow path extends from the second sub-column (e.g., SC13) of the first column (e.g., C1) to the first sub-column (e.g., SC21) of the second column (e.g., C2); e.g., see FIGS. 1F, 1H, 2D-2E, or the like.

In some embodiments regarding block 614, the communicating the data signal communicates a same such that the third flow path includes a second portion that extends from a row including the first SBFF region to a row including the (e.g., i)th SBFF region; e.g., see FIGS. 1A-1D, 1G, 1I, 2A-2B, 11, 2A-2E, or the like.

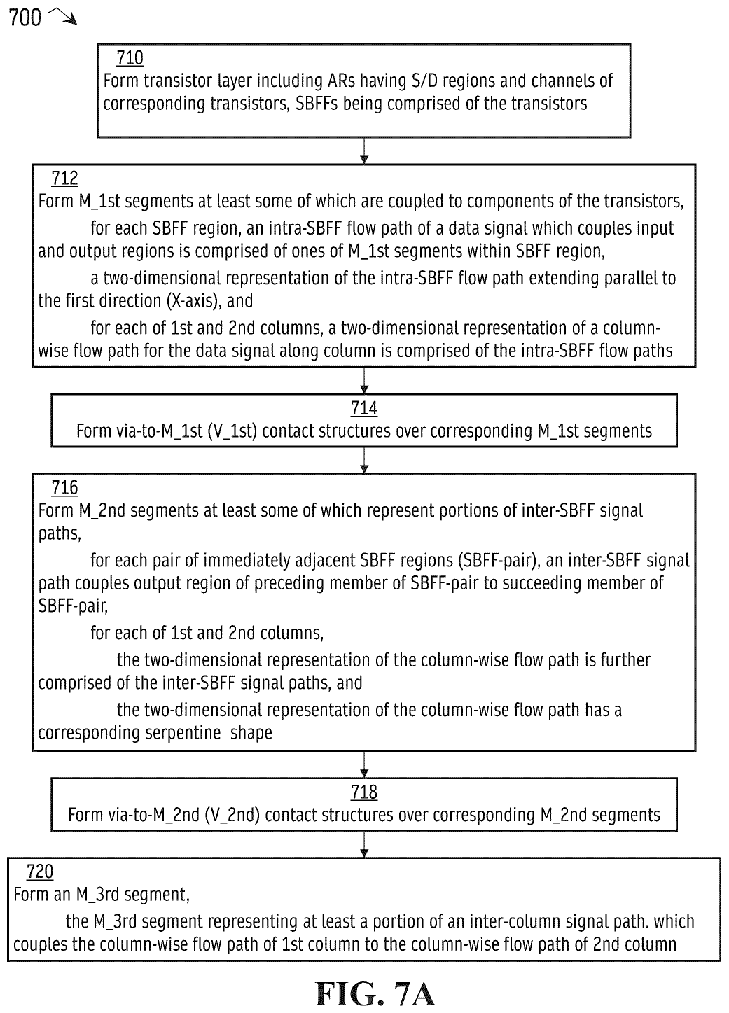

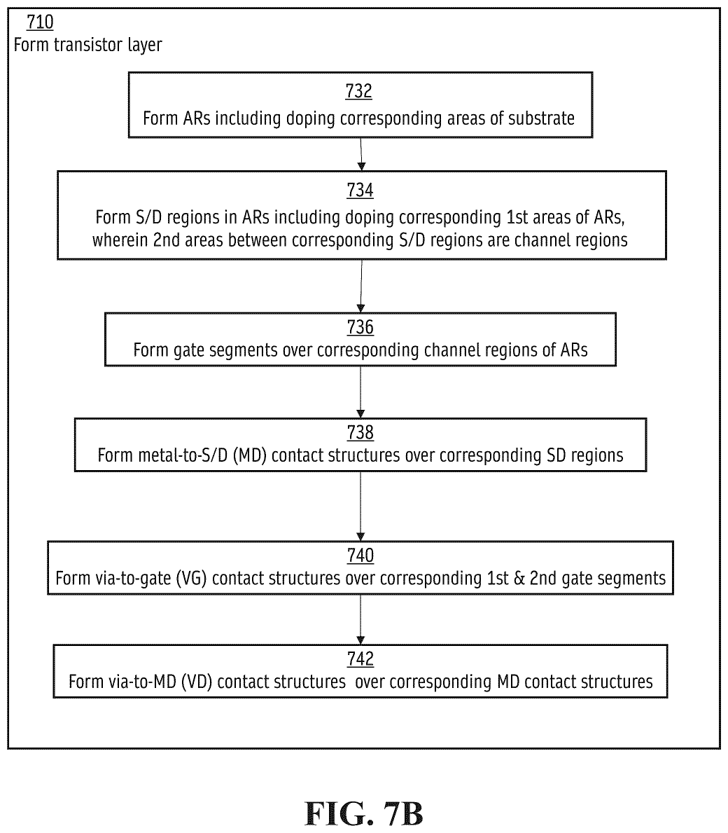

FIG. 7A is a flowchart 700 of a method of fabricating a multi-bit flip-flop (MBFF) region of a semiconductor device, in accordance with some embodiments.

FIG. 7B is a flowchart showing block 710 in more detail, in accordance with some embodiments.

Flowchart 700 includes blocks 710-720. The method of flowchart 700 is implementable, for example, using IC manufacturing system 900 (FIG. 9, discussed below), in accordance with some embodiments. Examples of a semiconductor device which can be manufactured according to the method of flowchart 700 include the semiconductor devices of FIGS. 1A-1H, semiconductor devices based on the layout diagrams disclosed herein, semiconductor devices based on the cross-sections disclosed herein, or the like.

Examples of MBFF regions fabricated according to flowchart 700 include MBFF regions corresponding to the block diagrams of FIGS. 1A-1I, MBFF regions corresponding to the layout diagrams of FIGS. 2A-2E, or the like.

An MBFF region fabricated according to flowchart 600 is comprised of first to (N)th single-bit flip-flops (SBFF regions) regions correspondingly representing bits b0 to b(N−1) such that the MBFF is an N-bit MBFF, where N is a positive integer. The first to (N)th SBFF regions (e.g., SBFF1-SBFF8 of FIGS. 1A-1B, 1E-1I, 2A-2E, SBFF1-SBFF12 of FIGS. 1C-1D, or the like) are daisy-chain coupled in a numerically increasing sequence from the first SBFF region to the (N)th SBFF region. The input of the first SBFF region represents the input of the MBFF region. The output of the (N)th SBFF region represents the output of the MBFF region. The MBFF region has a two-dimensional floor plan represented by a grid including rows (e.g., rows R1-R4 of FIGS. 1A-1B, 1E-1I, 2A-2E, rows R1-R6 of FIGS. 1C-1D, or the like) and first (C1) and second (C2) columns extending in corresponding first (e.g., parallel to the X-axis) and perpendicular second (e.g., parallel to the Y-axis) directions, each SBFF region representing an intersection of a corresponding row and column.

Regarding the MBFF region fabricated according to flowchart 600, the first column (e.g., C1 of FIGS. 1A-1I, 2A-2E, or the like) includes the first one of the SBFF regions to an (i+1)th one of the SBFF regions that correspondingly represent bits b(0) to b(i), where i is a positive integer and i<N. The second column (e.g. C2 of FIGS. 1A-1I, 2A-2E, or the like) includes an (i+2)th one of the SBFF regions to the (N)th SBFF region that correspondingly represent bits b(i+1) to b(N−1).

In FIG. 7A, at block 710, a transistor layer is formed that includes active regions (ARs) in corresponding areas of a substrate. An example of the transistor layer is transistor layer 320 of FIGS. 3A-3B, or the like. An example of the substrate is substrate 316 of FIG. 3B, or the like. Examples of the ARs include ARs AR 318N(16) of FIG. 3A, the ARs of FIGS. 2A-2E, or the like. From block 712, flow proceeds to block 712. Also at block 710, S/D regions are formed in locations in the ARs including doping areas of the ARs, wherein second areas between corresponding S/D regions are channel regions. Examples of the S/D regions include S/D regions 322(1)-322(2) of FIG. 3A, or the like. An example of a channel region is channel region 324 of FIG. 3B, or the like. From block 710, flow proceeds to block 712.

Block 710 includes blocks 732-742, as shown in FIG. 7B. At block 732, the ARs are formed including doping corresponding areas of the substrate. From block 732, flow proceeds to block 734. At block 734, the S/D regions are formed in the ARs including doping corresponding first areas of the ARs, wherein second areas between corresponding S/D regions are channel regions; see discussion of AR 318N(16) in the context of FIG. 3A. From block 734, flow proceeds to block 736.

At block 736, gate segments are formed over the substrate and over corresponding channel regions. An example of the gate segments is gate segment 322(1) in FIG. 3A, or the like. From block 736, flow proceeds to block 738.

At block 738, metal-to-S/D (MD) contact structures are formed over the substrate and over corresponding S/D regions. Examples of the MD contact structures include MD contact structures 334(1)-334(2) of FIGS. 3A-3B, or the like. From block 738, flow proceeds to block 740.

At block 740, via-to-gate (VG) contact structures are formed over corresponding gate segments. An example of the VG contact structure includes VG contact structure 336 in FIG. 3A, or the like. From block 7740, flow proceeds to block 742.

At block 742, via-to-MD (VD) contact structures are formed over corresponding MD contact structures. Examples of the VD contact structures include the instances of VD 338 in FIG. 3B, or the like. From block 742, flow exits block 710 and proceeds to block 712.

At block 712, M_1st segments (which are electrically conductive) are formed in a first layer of metallization (M_1st layer), at least some of which are coupled to components of the transistors. At least some of the M_1st segments are formed over corresponding instances of the VD contact structures. For each SBFF region being formed, an intra-SBFF flow path of a data signal which will couple input and output regions is comprised of ones of the M_1st segments within the SBFF region. A two-dimensional representation of the intra-SBFF flow path extends parallel to the first direction (e.g., parallel to the X-axis). For each of first and second columns, a two-dimensional representation of a column-wise flow path for the data signal along the column is comprised of the intra-SBFF flow paths. Examples of the M_1st segments include segments 340(1) and 340(2) in the M0 layer of FIG. 3A, or the like. In FIG. 3A, the M0 layer is an example of an M_1st layer. M_1st segment 340(1) in FIG. 3A is over VG 336. M_1st segment 340(2) in FIG. 3B is over instances of VD 338. From block 712, flow proceeds to block 714.

At block 714, via-to-M_1st (V_1st) contact structures are formed over corresponding ones of the M_1st segments. Examples of the V_1st contact structures include VIA0 contact structures 242 in FIGS. 2A-2E, VIA0 contact structures 342 in FIGS. 3A-3B, or the like. From block 714, flow proceeds to block 716.

At block 716, M_2nd segments (which are electrically conductive) are formed in a second layer of metallization (M_2nd layer), at least some of which represent portions of inter-SBFF signal paths. For each pair of immediately adjacent SBFF regions (SBFF-pair), a corresponding one of the inter-SBFF signal paths couples an output region of a preceding member of SBFF-pair to a succeeding member of SBFF-pair. For each of first and second columns, the two-dimensional representation of the column-wise flow path is further comprised of the inter-SBFF signal paths, and the two-dimensional representation of the column-wise flow path has a corresponding serpentine shape. Examples of the M_2nd segments include the M1(x) segments in FIGS. 2A-2E, M1 segments 344(1)-344(2) of FIGS. 3A-3B, or the like. From block 716, flow proceeds to block 718. Examples of the column-wise flow path having a serpentine shape include the portions of flow paths 106A-106I in each of columns C1 and C2 of corresponding FIGS. 1A-1I, the portions of the flow paths of FIGS. 2A-2E which are in each of columns C1 and C2 of FIGS. 2A-2E, or the like. From block 716, flow proceeds to block 718.

At block 718, via-to-M_2nd (V_2nd) contact structures are formed over corresponding ones of the M_2nd segments. Examples of the V_2nd contact structures include VIA1 contact structures 246 in FIGS. 2A-2E, VIA1 contact structure 346 in FIG. 3A, or the like. From block 718, flow proceeds to block 720.

At block 720, an M_3rd segment (which is electrically conductive) is formed in a third layer of metallization (M_3rd layer), the M_3rd segment representing at least a portion of an inter-column signal path. which couples the column-wise flow path of 1st column to the column-wise flow path of 2nd column. Examples of the M_3rd segment include the M2(x) segments in FIGS. 2A-2E, M2 segment 348(1) in FIG. 3A, or the like.

In some embodiments regarding block 720, the inter-column signal path is further comprised of one of the M_2nd segments in the first column (C_1st M_2nd segment) and one of the M_2nd segments in the second column (C2) (C_2nd M_2nd segment). Examples of the C_1st M_2nd segments include segments M1(7) in FIGS. 2A-2B, M1(9) in FIG. 2C, M1(17) in FIGS. 2D-2E, or the like. Examples of the C_2nd M_2nd segments include segments M1(8) in FIGS. 2A-2B, M1(10) in FIG. 2C, M1(18) in FIGS. 2D-2E, or the like.

In some embodiments regarding block 720, the C_1st M_2nd segment of the inter-column signal path overlies portions of at least two of the rows. Examples of such C_1st M_2nd segments include segments M1(7) in FIGS. 2A-2B, M1(9) in FIG. 2C, M1(17) in FIGS. 2D-2E, or the like.

In some embodiments regarding block 720, the C_2nd M_2nd segment of the inter-column signal path overlies portions of at least two of the rows. Examples of such C_2nd M_2nd segments include segments M1(8) in FIGS. 2A-2B, M1(10) in FIG. 2C, M1(18) in FIGS. 2D-2E, or the like.

In some embodiments regarding block 720, the C_1st M_2nd segment of the inter-column signal path extends from within the first SBFF region to the (i+1)th SBFF region to within. Examples of such C_1st M_2nd segments include segments M1(7) in FIGS. 2A-2B, or the like.

FIG. 8 is a block diagram of an electronic design automation (EDA) system 800 in accordance with some embodiments.

In some embodiments, EDA system 800 includes an automatic placement and routing (APR) system. In some embodiments, EDA system 800 is a general purpose computing device including a hardware processor 802 and a non-transitory, computer-readable storage medium 804. Storage medium 804, amongst other things, is encoded with, i.e., stores, computer program code 806, i.e., a set of executable instructions. Execution of instructions 806 by hardware processor 802 represents (at least in part) an EDA tool which implements a portion or all of, e.g., the method of FIG. 5 (block 502), methods of generating layout diagrams such as FIGS. 2A-2E, methods of generating layout diagrams corresponding to block diagrams such as FIGS. 1A-1H, or the like, in accordance with one or more embodiments (hereinafter, the noted processes and/or methods). Storage medium 804, amongst other things, stores layout diagrams 811 such as the layout diagrams disclosed herein, other the like.

Processor 802 is electrically coupled to computer-readable storage medium 804 via a bus 808. Processor 802 is further electrically coupled to an I/O interface 810 by a bus 808. A network interface 812 is further electrically connected to processor 802 via bus 808. Network interface 812 is connected to a network 814, so that processor 802 and computer-readable storage medium 804 are capable of connecting to external elements via network 814. Processor 802 is configured to execute computer program code 806 encoded in computer-readable storage medium 804 in order to cause system 800 to be usable for performing a portion or all of the noted processes and/or methods. In one or more embodiments, processor 802 is a central processing unit (CPU), a multi-processor, a distributed processing system, an application specific integrated circuit (ASIC), and/or a suitable processing unit.

In one or more embodiments, computer-readable storage medium 804 is an electronic, magnetic, optical, electromagnetic, infrared, and/or a semiconductor system (or apparatus or device). For example, computer-readable storage medium 804 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 804 includes a compact disk-read only memory (CD-ROM), a compact disk-read/write (CD-R/W), and/or a digital video disc (DVD).

In one or more embodiments, storage medium 804 stores computer program code 806 configured to cause system 800 (where such execution represents (at least in part) the EDA tool) to be usable for performing a portion or all of the noted processes and/or methods. In one or more embodiments, storage medium 804 further stores information which facilitates performing a portion or all of the noted processes and/or methods. In one or more embodiments, storage medium 804 stores library 707 of standard cells including such standard cells as disclosed herein. In some embodiments, storage medium 804 stores one or more layout diagrams 811.

EDA system 800 includes I/O interface 810. I/O interface 810 is coupled to external circuitry. In one or more embodiments, I/O interface 810 includes a keyboard, keypad, mouse, trackball, trackpad, touchscreen, and/or cursor direction keys for communicating information and commands to processor 802.

EDA system 800 further includes network interface 812 coupled to processor 802. Network interface 812 allows system 800 to communicate with network 814, to which one or more other computer systems are connected. Network interface 812 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 800.

System 800 is configured to receive information through I/O interface 810. The information received through I/O interface 810 includes one or more of instructions, data, design rules, libraries of standard cells, and/or other parameters for processing by processor 802. The information is transferred to processor 802 via bus 808. EDA system 800 is configured to receive information related to a user interface (UI) through I/O interface 810. The information is stored in computer-readable medium 804 as UI 842.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 800. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 9 is a block diagram of an integrated circuit (IC) manufacturing system 900, and an IC manufacturing flow associated therewith, in accordance with some embodiments.

Based on the layout diagram generated by block 502 of FIG. 5A, the IC manufacturing system 900 implements block 504 of FIG. 5A wherein at least one of (A) one or more semiconductor masks or (B) at least one component in a layer of an inchoate semiconductor integrated circuit is fabricated using manufacturing system 900.

In FIG. 9, IC manufacturing system 900 includes entities, such as a design house 920, a mask house 930, and an IC manufacturer/fabricator (“fab”) 950, that interact with one another in the design, development, and manufacturing cycles and/or services related to manufacturing an IC device 960. The entities in system 900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and supplies services to and/or receives services from one or more of the other entities. In some embodiments, two or more of design house 920, mask house 930, and IC fab 950 is owned by a single larger company. In some embodiments, two or more of design house 920, mask house 930, and IC fab 950 coexist in a common facility and use common resources.

Design house (or design team) 920 generates an IC design layout 922. IC design layout 922 includes various geometrical patterns designed for an IC device 960. The geometrical patterns correspond to patterns of metal, oxide, or semiconductor layers that make up the various components of IC device 960 to be fabricated. The various layers combine to form various IC features. For example, a portion of IC design layout 922 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Source/drain region(s) may refer to a source or a drain, individually or collectively, dependent upon the context. Design house 920 implements a proper design procedure to form IC design layout 922. The design procedure includes one or more of logic design, physical design or place and route. IC design layout 922 is presented in one or more data files having information of the geometrical patterns. For example, IC design layout 922 is expressed in a GDSII file format or DFII file format.

Mask house 930 includes data preparation 932 and mask fabrication 934. Mask house 930 uses IC design layout 922 to manufacture one or more masks 935 to be used for fabricating the various layers of IC device 960 according to IC design layout 922. Mask house 930 performs mask data preparation 932, where IC design layout 922 is translated into a representative data file (“RDF”). Mask data preparation 932 supplies the RDF to mask fabrication 934. Mask fabrication 934 includes a mask writer. A mask writer converts the RDF to an image on a substrate, such as a mask (reticle) or a semiconductor wafer. The design layout is manipulated by mask data preparation 932 to comply with particular characteristics of the mask writer and/or requirements of IC fab 950. In FIG. 9, mask data preparation 932, mask fabrication 934, and mask 935 are illustrated as separate elements. In some embodiments, mask data preparation 932 and mask fabrication 934 are collectively referred to as mask data preparation.

In some embodiments, mask data preparation 932 includes optical proximity correction (OPC) which uses lithography enhancement techniques to compensate for image errors, such as those that can arise from diffraction, interference, other process effects and the like. OPC adjusts IC design layout 922. In some embodiments, mask data preparation 932 includes further resolution enhancement techniques (RET), such as off-axis illumination, sub-resolution assist features, phase-shifting masks, other suitable techniques, and the like or combinations thereof. In some embodiments, inverse lithography technology (ILT) is further used, which treats OPC as an inverse imaging problem.

In some embodiments, mask data preparation 932 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 934, which may undo part of the modifications performed by OPC in order to meet mask creation rules.

In some embodiments, mask data preparation 932 includes lithography process checking (LPC) that simulates processing that will be implemented by IC fab 950 to fabricate IC device 960. LPC simulates this processing based on IC design layout 922 to fabricate a simulated manufactured device, such as IC device 960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been fabricated by LPC, if the simulated device is not close enough in shape to satisfy design rules, OPC and/or MRC are be repeated to further refine IC design layout 922.

The above description of mask data preparation 932 has been simplified for the purposes of clarity. In some embodiments, mask data preparation 932 includes additional features such as a logic operation (LOP) to modify the IC design layout according to manufacturing rules. Additionally, the processes applied to IC design layout 922 during data preparation 932 may be executed in a variety of different orders.

After mask data preparation 932 and during mask fabrication 934, a mask 935 or a group of masks 935 are fabricated based on the modified IC design layout. In some embodiments, an electron-beam (e-beam) or a mechanism of multiple e-beams is used to form a pattern on a mask (photomask or reticle) based on the modified IC design layout. The masks are formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask is an attenuated PSM or alternating PSM. The mask(s) generated by mask fabrication 934 is used in a variety of processes. For example, such a mask(s) is used in an ion implantation process to form various doped regions in the semiconductor wafer, in an etching process to form various etching regions in the semiconductor wafer, and/or in other suitable processes.

IC fab 950 is an IC fabrication business that includes one or more manufacturing facilities for the fabrication of a variety of different IC products. In some embodiments, IC fab 950 is a semiconductor foundry. For example, there may be a manufacturing facility for the front end fabrication of a plurality of IC products (front-end-of-line (FEOL) fabrication), while a second manufacturing facility may supply the back end fabrication for the interconnection and packaging of the IC products (back-end-of-line (BEOL) fabrication), and a third manufacturing facility may supply other services for the foundry business.

IC fab 950 uses mask (or masks) 935 fabricated by mask house 930 to fabricate IC device 960 using fabrication tools 952. Thus, IC fab 950 at least indirectly uses IC design layout 922 to fabricate IC device 960. In some embodiments, a semiconductor wafer 953 is fabricated by IC fab 950 using mask (or masks) 935 to form IC device 960. Semiconductor wafer 953 includes a silicon substrate or other proper substrate having material layers formed thereon. Semiconductor wafer further includes one or more of various doped regions, dielectric features, multilevel interconnects, and the like (formed at subsequent manufacturing steps).

In some embodiments, a semiconductor device includes single-bit flip-flops (SBFF regions) regions which comprise a multi-bit flip-flop (MBFF) region; the MBFF region having a two-dimensional floor plan represented by a grid including rows and a first column extending in corresponding first and perpendicular second directions, each SBFF region representing an intersection of a corresponding row and column; the SBFF regions being coupled in a daisy chain for which an output of a preceding one of the SBFF regions in the daisy chain is coupled to an input of a succeeding one of the SBFF regions in the daisy chain; and orientations of the SBFF regions relative to the first direction (α-orientations) being arranged in an alternating pattern relative to the second direction so that a two-dimensional representation of a flow path of a data signal along the first column has a serpentine shape.

In some embodiments, the first column includes at least first and second sub-columns; relative to the first direction, each SBFF region has an input region at a first side of the SBFF region and an output region at an opposite second side of the SBFF region; for each SBFF region in odd rows of each of the first column, the input region is in the first sub-column and the output region is in the second sub-column; and for each SBFF region in even rows of the first column, the input region is in the second sub-column and the output region is in the first sub-column.

In some embodiments, the grid further includes a second column extending in the second direction, the second column including at least first and second sub-columns; for each SBFF region in odd rows of the second column, the input region is in the second sub-column and the output region is in the first sub-column; and for each SBFF region in even rows of each of the first column, the input region is in the first sub-column and the output region is in the second sub-column.

In some embodiments, the grid further includes a second column extending in the second direction; for each SBFF region in odd rows of each of the second column, the input region is in the first sub-column and the output region is in the second sub-column; and for each SBFF region in even rows of the second column, the input region is in the second sub-column and the output region is in the first sub-column.

In some embodiments, the grid further includes a second column extending in the second direction; each of the first and second columns includes at least first and second sub-columns; relative to the first direction, each SBFF region has an input region at a first side of the SBFF region and an output region at an opposite second side of the SBFF region; for each SBFF region in odd rows of each of the first and second columns, the input region is in the second sub-column and the output region is in the first sub-column; for each SBFF region in even rows of each of the first and second columns, the input region is in the first sub-column and the output region is in the second sub-column.

In some embodiments, the semiconductor device further includes: a transistor layer including active regions (ARs) in which are formed source/drain (S/D) regions and channel regions of corresponding transistors, the channel regions being correspondingly between the S/D regions being channel regions, the SBFF regions being comprised of corresponding ones of the transistors; and wherein: some of the ARs have a first type of conductivity (first ARs) and some of the ARs have a different second type of conductivity (second ARs); each SBFF includes at least one first AR and at least one second AR; each SBFF has a first orientation or a second orientation relative to the second direction (first β-orientation or second β-orientation), the first β-orientation having the first AR stacked on the second AR, and the second β-orientation having the second AR stacked on the first AR; and for each SBFF region in odd rows, the SBFF region has the first β-orientation.

In some embodiments, for each SBFF region in even rows, the SBFF region has the first β-orientation.

In some embodiments, for each SBFF region in even rows, the SBFF region has the second β-orientation.

In some embodiments, the semiconductor device further includes: a transistor layer including active regions (ARs) in which are formed source/drain (S/D) regions and channel regions of corresponding transistors, the channel regions being correspondingly between the S/D regions being channel regions, the SBFF regions being comprised of corresponding ones of the transistors; and wherein: some of the ARs have a first type of conductivity (first ARs) and some of the ARs have a different second type of conductivity (second ARs); each SBFF includes at least one first AR and at least one second AR; each SBFF has a first orientation or a second orientation relative to the second direction (first β-orientation or second β-orientation), the first β-orientation having the first AR stacked on the second AR, and the second β-orientation having the second AR stacked on the first AR; and for each SBFF region in even rows, the SBFF region has the second β-orientation.

In some embodiments, for each SBFF region in odd rows of the first column, the SBFF region has the first β-orientation.

In some embodiments, for each SBFF region in odd rows of the first column, the SBFF region has the second β-orientation.

In some embodiments, the grid further includes a second column extending in the second direction; the semiconductor device further includes a transistor layer including active regions (ARs) in which are formed source/drain (S/D) regions and channel regions of corresponding transistors, the channel regions being correspondingly between the S/D regions being channel regions, the SBFF regions being comprised of corresponding ones of the transistors; a first layer of metallization (M_1st layer) over the transistor layer, conductive segments in the M_1st layer (M_1st segments) extending in the first direction; a second layer of metallization (M_2nd layer) over the M_1st layer, conductive segments in the M_2nd layer (M_2nd segments) extending in the second direction; and a third layer of metallization (M_3rd layer) over the M_2nd layer, conductive segments in the M_3rd layer (M_3rd segments) extending in the first direction; the SBFF regions in the first column represent bits b0 to b(i) of the MBFF, where i is a positive integer and i<N; the SBFF regions in the second column represent bits b(i+1) to b(N−1) of the MBFF; a coupling between the output of the SBFF region representing bit b(i) in the first column and the SBFF region representing bit b(i+1) in the second column includes a first one of the M_3rd segments; and for each of the first and second columns, portions of the daisy chain that couple an input of a given SBFF region to an output of a given SBFF region are free from including an M_3rd segment.

In some embodiments, in each of the first and second columns, relative to the second direction, the SBFF regions are arranged in a stack in which the SBFF regions are stacked on each other; and the coupling between the output of the SBFF region representing bit b(i) in the first column and the SBFF region representing bit b(i+1) in the second column includes a first M_2nd segment, the first M_2nd segment extending from the SBFF region representing bit b0 in the first column to the SBFF region representing bit b(i) in the first column.

In some embodiments, an input of the SBFF region representing a head of the daisy chain represents an input of the MBFF region, an output of the SBFF region representing a tail of the daisy chain represents an output of the MBFF region.

In some embodiments, the grid further includes a second column extending in the second direction; a first half of a total number of the SBFF regions is in the first column; a second half of the total number of the SBFF regions is in the second column.

In some embodiments, in the first column, the serpentine shape of the flow path of the data signal along the first column is a non-self-overlapping serpentine shape.

In some embodiments, in the first column, the serpentine shape of the flow path of the data signal along the first column is a self-overlapping serpentine shape.

In some embodiments, a semiconductor device includes single-bit flip-flops (SBFF region) regions which comprise a multi-bit flip-flop (MBFF) region; the MBFF region having a two-dimensional floor plan represented by a grid including rows and first and second columns, extending in corresponding first and perpendicular second directions, each SBFF region representing an intersection of a corresponding row and column; the SBFF regions being coupled in a daisy chain for which an output of a preceding one of the SBFF regions in the daisy chain is coupled to an input of a succeeding one of the SBFF regions in the daisy chain; and orientations of the SBFF regions relative to the first direction (α-orientations) being arranged in an alternating pattern relative to the second direction so that a two-dimensional representation of a flow path of a data signal along each of the first and second columns has a corresponding serpentine shape.

In some embodiments, the SBFF regions include first to (N)th SBFF regions such that the MBFF is an N-bit MBFF, where N is a positive integer; the daisy chain couples the first to (N)th SBFF regions in a numerically increasing sequence from the first SBFF region to the (N)th SBFF region; in each of the first and second columns, relative to the second direction, the SBFF regions are arranged in a stack in which the SBFF regions are stacked on each other; the SBFF regions in the first column represent bits b0 to b(i) of the MBFF, where i is a positive integer and i<N; relative to the second direction, the SBFF region representing bit b0 is at a bottom of the first column, and the SBFF region representing bit b(i) is at a top of the first column.

In some embodiments, the SBFF regions in the second column represent bits b(i+1) to b(N−1) of the MBFF; relative to the second direction, the SBFF region representing bit b(i+1) is at a bottom of the second column, and the SBFF region representing bit b(N−1) is at a top of the second column.

In some embodiments, the SBFF regions in the second column represent bits b(i+1) to b(N−1); relative to the second direction, the SBFF region representing bit b(i+1) is at a top of the first column, and the SBFF region representing bit b(N−1) is at a bottom of the first column.

In some embodiments, a method of operating a multi-bit flip-flop (MBFF) region of a semiconductor device, the MBFF being comprised of first to (N)th single-bit flip-flops (SBFF regions) regions correspondingly representing bits b0 to b(N−1) such that the MBFF is an N-bit MBFF, where N is a positive integer, the first to (N)th SBFF regions being daisy-chain coupled in a numerically increasing sequence from the first SBFF region to the (N)th SBFF region, the MBFF region having a two-dimensional floor plan represented by a grid including rows and first and second columns extending in corresponding first and perpendicular second directions, each SBFF region representing an intersection of a corresponding row and column, the first column including the first SBFF region to an (i+1)th one of the SBFF regions that correspondingly represent bits b(0) to b(i), where i is a positive integer and i<N, the second column including an (i+2)th one of the SBFF regions to the (N)th SBFF region that correspondingly represent bits b(i+1) to b(N−1), the method including advancing a data signal through the MBFF region which includes: propagating the data signal in the first column such that a two-dimensional representation of a first flow path of the data signal along the first column has a first serpentine shape; propagating the data signal from the first column to the second column; and propagating the data signal in the second column such that a two-dimensional representation of a second flow path of the data signal along the second column has a second serpentine shape.

In some embodiments, the propagating the data signal in the first column propagates the data signal such the two-dimensional representation of the first flow path has a non-self-overlapping serpentine shape; and the propagating the data signal in the second column propagates the data signal such the two-dimensional representation of the second flow path has a non-self-overlapping serpentine shape.

In some embodiments, the propagating the data signal in the first column propagates the data signal such the two-dimensional representation of the first flow path has a self-overlapping serpentine shape; and the propagating the data signal in the second column propagates the data signal such the two-dimensional representation of the second flow path has a self-overlapping serpentine shape.

In some embodiments, each SBFF region has an input region at a first side of the SBFF region and an output region at an opposite second side of the SBFF region relative to the first direction, each of the first and second columns includes at least first and second sub-columns, a first orientation for a given one of the SBFF regions relative to the first direction (α-orientation) has the input region in the first sub-column and the output region in the second sub-column, a second α-orientation for a given one of the SBFF regions has the input region in the second sub-column and the output region in the first sub-column, for each of the first and second columns, the rows exhibit an alternating pattern of α-orientations such that the rows alternate between the first and second α-orientations, the propagating the data signal in the first column includes communicating the data signal such that each portion of the two-dimensional representation of the first flow path which couples a preceding one of the first to (i+1)th SBFF regions to a succeeding one of the first to (i+1)th SBFF regions is parallel to the second direction; and the propagating the data signal in the second column includes communicating the data signal such that each portion of the two-dimensional representation of the second flow path which couples a preceding one of the (i+2)th to (N)th SBFF regions to a succeeding one of the (i+2)th to (N)th SBFF regions is parallel to the second direction.

In some embodiments, the propagating the data signal from the first column to the second column includes communicating the data signal such that a two-dimensional representation of a third flow path of the data signal from the first column to the second column includes a first portion that is parallel to the first direction.

In some embodiments, the communicating the data signal communicates a same such that the first portion extends from the first sub-column of the first column to the second sub-column of the second column.

In some embodiments, the communicating the data signal communicates a same such that the first portion extends from the first sub-column of the first column to the first sub-column of the second column.

In some embodiments, the communicating the data signal communicates a same such that the first portion extends from the second sub-column of the first column to the first sub-column of the second column.

In some embodiments, the propagating the data signal from the first column to the second column includes communicating the data signal such that the two-dimensional representation of the third flow path further includes a second portion extends from a row including the first SBFF region to a row including the (i)th SBFF region.

In some embodiments, a method of forming a multi-bit flip-flop (MBFF) region of a semiconductor device, the MBFF being comprised of first to (N)th single-bit flip-flops (SBFF regions) regions correspondingly representing bits b0 to b(N−1) such that the MBFF is an N-bit MBFF, where N is a positive integer, the first to (N)th SBFF regions being daisy-chain coupled in a numerically increasing sequence from the first SBFF region to the (N)th SBFF region, the MBFF region having a two-dimensional floor plan represented by a grid including rows and first and second columns extending in corresponding first and perpendicular second directions, each SBFF region representing an intersection of a corresponding row and column, the first column including the first SBFF region to an (i+1)th one of the SBFF regions that correspondingly represent bits b(0) to b(i), where i is a positive integer and i<N, the second column including an (i+2)th one of the SBFF regions to the (N)th SBFF region that correspondingly represent bits b(i+1) to b(N−1), the method including: forming a transistor layer, the transistor layer including active regions (ARs) in which are formed source/drain (S/D) regions and channel regions of corresponding transistors, the channel regions being correspondingly between the S/D regions being channel regions, the SBFF regions being comprised of corresponding ones of the transistors; forming segments (M_1st segments) in a first layer of metallization over the transistor layer, the M_1st segments extending in the first direction, at least some of the M_1st segments being coupled to corresponding components of the transistors including the S/D regions, each SBFF region having an input region at a first side of the SBFF region and an output region at an opposite second side of the SBFF region relative to the first direction, for each SBFF region, an intra-SBFF flow path of a data signal which couples the input region and the output region is comprised of ones of the M_1st segments within the SBFF region relative to the second direction (intra-SBFF segments), a two-dimensional representation of the intra-SBFF flow path extending parallel to the first direction, and for each of the first and second columns, a two-dimensional representation of a column-wise flow path for the data signal along the column is comprised of the intra-SBFF flow paths; and forming segments in a second layer of metallization (M_2nd segments), the M_2nd segments extending in the second direction, at least some of the M_2nd segments representing portions of inter-SBFF signal paths, for each pair of immediately adjacent SBFF regions (SBFF-pair) relative to the second direction, a corresponding one of the inter-SBFF signal paths couples the output region of a preceding member of the SBFF-pair to a succeeding member of the SBFF-pair, for each of the first and second columns, the two-dimensional representation of the column-wise flow path is further comprised of the inter-SBFF signal paths, and for each of the first and second columns, the two-dimensional representation of the column-wise flow path has a corresponding serpentine shape.

In some embodiments, the forming a transistor layer includes: forming active regions (ARs) in a substrate, the ARs extending in a first direction; forming source/drain (S/D) regions in the ARs including doping first areas of the ARs, and wherein second areas of the ARs which are correspondingly between the S/D regions are channel regions; forming gate segments correspondingly over the channel regions of the ARs and extending in a second direction perpendicular to the first direction; forming metal-to-source/drain region (MD) contact structures correspondingly over the ARs and interspersed with the gate segments; forming via-to-gate (VG) contact structures correspondingly over the gate segments and under corresponding ones of the M_1st segments; and forming via-to-MD (VD) contact structures correspondingly over the MD contact structures; and wherein the M_1st segments are correspondingly over the VG contact structures and the VD contact structures.

In some embodiments, before the forming M_2nd segments, forming via-to-M_1st (V_1st) contact structures correspondingly over the M_1st segments); and wherein the M_2nd segments are correspondingly over the V_1st contact structures.

In some embodiments, the method further includes forming a segment in a third layer of metallization (M_3rd segment), the M_3rd segment extending in the second direction, the M_3rd segment representing at least a portion of an inter-column signal path which couples the column-wise flow path of the first column to the column-wise flow path of the second column.

In some embodiments, the inter-column signal path is further comprised of one of the M_2nd segments in the first column (C_1st M_2nd segment) and one of the M_2nd segments in the second column (C_2nd M_2nd segment).

In some embodiments, the C_1st M_2nd segment of the inter-column signal path overlies portions of at least two of the rows; or the C_2nd M_2nd segment of the inter-column signal path overlies portions of at least two of the rows.

In some embodiments, the C_1st M_2nd segment of the inter-column signal path extends from within the first SBFF region to the (i+1)th SBFF region.

In some embodiments, before the forming the M_3rd segment), forming a via-to-M_2nd (VIA2) contact structure over the M_2nd segment.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

What is claimed is:

1. A semiconductor device comprising:
single-bit flip-flop regions (SBFF regions) which comprise a multi-bit flip-flop (MBFF) region;
the MBFF region having a two-dimensional floor plan represented by a grid including rows and a first column extending in corresponding first and perpendicular second directions, each SBFF region representing an intersection of a corresponding row and column;
the SBFF regions being coupled in a daisy chain for which an output of a preceding one of the SBFF regions in the daisy chain is coupled to an input of a succeeding one of the SBFF regions in the daisy chain; and
orientations of the SBFF regions relative to the first direction (α-orientations) being arranged in an alternating pattern relative to the second direction so that a two-dimensional representation of a flow path of a data signal along the first column has a serpentine shape.

2. The semiconductor device of claim 1, wherein:
the first column includes at least first and second sub-columns;
relative to the first direction, each SBFF region has an input region at a first side of the SBFF region and an output region at an opposite second side of the SBFF region;
for each SBFF region in odd rows of each of the first column, the input region is in the first sub-column and the output region is in the second sub-column; and
for each SBFF region in even rows of the first column, the input region is in the second sub-column and the output region is in the first sub-column.

3. The semiconductor device of claim 2, wherein:
the grid further includes a second column extending in the second direction, the second column including at least first and second sub-columns;
for each SBFF region in odd rows of the second column, the input region is in the second sub-column and the output region is in the first sub-column; and
for each SBFF region in even rows of each of the first column, the input region is in the first sub-column and the output region is in the second sub-column.

4. The semiconductor device of claim 2, wherein:
the grid further includes a second column extending in the second direction;
for each SBFF region in odd rows of each of the second column, the input region is in the first sub-column and the output region is in the second sub-column; and
for each SBFF region in even rows of the second column, the input region is in the second sub-column and the output region is in the first sub-column.

5. The semiconductor device of claim 1, wherein:
the grid further includes a second column extending in the second direction;
each of the first and second columns includes at least first and second sub-columns;
relative to the first direction, each SBFF region has an input region at a first side of the SBFF region and an output region at an opposite second side of the SBFF region;
for each SBFF region in odd rows of each of the first and second columns, the input region is in the second sub-column and the output region is in the first sub-column;
for each SBFF region in even rows of each of the first and second columns, the input region is in the first sub-column and the output region is in the second sub-column.

6. The semiconductor device of claim 1, wherein:
the grid further includes a second column extending in the second direction;
the semiconductor device further comprises:
a transistor layer including active regions (ARs) in which are formed source/drain (S/D) regions and channel regions of corresponding transistors, the channel regions being correspondingly between the S/D regions being channel regions, the SBFF regions being comprised of corresponding ones of the transistors;
a first layer of metallization (M_1st layer) over the transistor layer, conductive segments in the M_1st layer (M_1st segments) extending in the first direction;
a second layer of metallization (M_2nd layer) over the M_1st layer, conductive segments in the M_2nd layer (M_2nd segments) extending in the second direction; and
a third layer of metallization (M_3rd layer) over the M_2nd layer, conductive segments in the M_3rd layer (M_3rd segments) extending in the first direction;
the SBFF regions in the first column represent bits b0 to b(i) of the MBFF, where i is a positive integer and i<N;
the SBFF regions in the second column represent bits b(i+1) to b(N−1) of the MBFF;
a coupling between the output of the SBFF region representing bit b(i) in the first column and the SBFF region representing bit b(i+1) in the second column includes a first one of the M_3rd segments; and
for each of the first and second columns, portions of the daisy chain that couple an input of a given SBFF region to an output of a given SBFF region are free from including an M_3rd segment.

7. The semiconductor device of claim 6, wherein:
in each of the first and second columns, relative to the second direction, the SBFF regions are arranged in a stack in which the SBFF regions are stacked on each other; and
the coupling between the output of the SBFF region representing bit b(i) in the first column and the SBFF region representing bit b(i+1) in the second column includes a first M_2nd segment, the first M_2nd segment extending from the SBFF region representing bit b0 in the first column to the SBFF region representing bit b(i) in the first column.

8. The semiconductor device of claim 1, wherein:
in the first column, the serpentine shape of the flow path of the data signal along the first column is a non-self-overlapping serpentine shape.

9. The semiconductor device of claim 1, wherein:
in the first column, the serpentine shape of the flow path of the data signal along the first column is a self-overlapping serpentine shape.

10. A semiconductor device comprising:
single-bit flip-flop regions (SBFF regions) which comprise a multi-bit flip-flop (MBFF) region;
the MBFF region having a two-dimensional floor plan represented by a grid including rows and first and second columns, extending in corresponding first and perpendicular second directions, each SBFF region representing an intersection of a corresponding row and column;
the SBFF regions being coupled in a daisy chain for which an output of a preceding one of the SBFF regions in the daisy chain is coupled to an input of a succeeding one of the SBFF regions in the daisy chain; and
orientations of the SBFF regions relative to the first direction (α-orientations) being arranged in an alternating pattern relative to the second direction so that a two-dimensional representation of a flow path of a data signal along each of the first and second columns has a corresponding serpentine shape.

11. The semiconductor device of claim 10, wherein:
the SBFF regions include first to (N)th SBFF regions such that the MBFF is an N-bit MBFF, where N is a positive integer;
the daisy chain couples the first to (N)th SBFF regions in a numerically increasing sequence from the first SBFF region to the (N)th SBFF region;
in each of the first and second columns, relative to the second direction, the SBFF regions are arranged in a stack in which the SBFF regions are stacked on each other;
the SBFF regions in the first column represent bits b0 to b(i) of the MBFF, where i is a positive integer and i<N;
relative to the second direction,
the SBFF region representing bit b0 is at a bottom of the first column, and
the SBFF region representing bit b(i) is at a top of the first column.

12. The semiconductor device of claim 11, wherein:
the SBFF regions in the second column represent bits b(i+1) to b(N−1) of the MBFF;
relative to the second direction,
the SBFF region representing bit b(i+1) is at a bottom of the second column, and
the SBFF region representing bit b(N−1) is at a top of the second column.

13. The semiconductor device of claim 11, wherein:
the SBFF regions in the second column represent bits b(i+1) to b(N−1);
relative to the second direction,
the SBFF region representing bit b(i+1) is at a top of the first column, and
the SBFF region representing bit b(N−1) is at a bottom of the first column.

14. A method of operating a multi-bit flip-flop (MBFF) region of a semiconductor device, the MBFF being comprised of first to (N)th single-bit flip-flop regions (SBFF regions) correspondingly representing bits b0 to b(N−1) such that the MBFF is an N-bit MBFF, where N is a positive integer,
the first to (N)th SBFF regions being daisy-chain coupled in a numerically increasing sequence from the first SBFF region to the (N)th SBFF region,
the MBFF region having a two-dimensional floor plan represented by a grid including rows and first and second columns extending in corresponding first and perpendicular second directions, each SBFF region representing an intersection of a corresponding row and column,
the first column including the first SBFF region to an (i+1)th one of the SBFF regions that correspondingly represent bits b(0) to b(i), where i is a positive integer and i<N,
the second column including an (i+2)th one of the SBFF regions to the (N)th SBFF region that correspondingly represent bits b(i+1) to b(N−1),
the method comprising advancing a data signal through the MBFF region including:
propagating the data signal in the first column such that a two-dimensional representation of a first flow path of the data signal along the first column has a first serpentine shape;
propagating the data signal from the first column to the second column; and
propagating the data signal in the second column such that a two-dimensional representation of a second flow path of the data signal along the second column has a second serpentine shape.

15. The method of claim 14, wherein:
the propagating the data signal in the first column propagates the data signal such the two-dimensional representation of the first flow path has a non-self-overlapping serpentine shape; and
the propagating the data signal in the second column propagates the data signal such the two-dimensional representation of the second flow path has a non-self-overlapping serpentine shape.

16. The method of claim 14, wherein:
the propagating the data signal in the first column propagates the data signal such the two-dimensional representation of the first flow path has a self-overlapping serpentine shape; and
the propagating the data signal in the second column propagates the data signal such the two-dimensional representation of the second flow path has a self-overlapping serpentine shape.

17. The method of claim 14, wherein:
each SBFF region has an input region at a first side of the SBFF region and an output region at an opposite second side of the SBFF region relative to the first direction,
each of the first and second columns includes at least first and second sub-columns,
a first orientation for a given one of the SBFF regions relative to the first direction (α-orientation) has the input region in the first sub-column and the output region in the second sub-column,
a second α-orientation for a given one of the SBFF regions has the input region in the second sub-column and the output region in the first sub-column,
for each of the first and second columns, the rows exhibit an alternating pattern of α-orientations such that the rows alternate between the first and second α-orientations,
the propagating the data signal in the first column includes communicating the data signal such that each portion of the two-dimensional representation of the first flow path which couples a preceding one of the first to (i+1)th SBFF regions to a succeeding one of the first to (i+1)th SBFF regions is parallel to the second direction; and
the propagating the data signal in the second column includes communicating the data signal such that each portion of the two-dimensional representation of the second flow path which couples a preceding one of the (i+2)th to (N)th SBFF regions to a succeeding one of the (i+2)th to (N)th SBFF regions is parallel to the second direction.

18. The method of claim 14, wherein the propagating the data signal from the first column to the second column includes:
communicating the data signal such that a two-dimensional representation of a third flow path of the data signal from the first column to the second column includes a first portion that is parallel to the first direction.

19. The method of claim 18, wherein:
the communicating the data signal communicates a same such that the first portion extends from the first sub-column of the first column to the second sub-column of the second column.

20. The method of claim 18, wherein the propagating the data signal from the first column to the second column includes:
communicating the data signal such that the two-dimensional representation of the third flow path further includes a second portion extends from a row including the first SBFF region to a row including the (i)th SBFF region.
